(19) United States
(12) Patent Application Publication
(10) Pub. No.: US 2025/0275437 A1
(43) Pub. Date: Aug. 28, 2025

(54) DISPLAY DEVICE AND METHOD OF MANUFACTURING THE SAME

(71) Applicant: Samsung Display Co., LTD., Yongin-si (KR)

(72) Inventors: Ki Chang EOM, Yongin-si (KR); Young Kyo SEO, Yongin-si (KR); So Yeon YOON, Yongin-si (KR); Gwang Geun LEE, Yongin-si (KR)

(73) Assignee: Samsung Display Co., LTD., Yongin-si (KR)

(21) Appl. No.: 18/965,293

(22) Filed: Dec. 2, 2024

(30) Foreign Application Priority Data
Feb. 22, 2024 (KR) 10-2024-0025924

(51) Int. Cl. H10K 59/80; H10K 59/12; H10K 59/122; H10K 59/38

(52) U.S. Cl. CPC H10K 59/877; H10K 59/1201; H10K 59/122; H10K 59/38; H10K 59/878

(57) ABSTRACT

A display device includes light emitting elements disposed on a pixel circuit layer, light extraction structures spaced apart from each other on the pixel circuit layer that overlap the light emitting elements, a first bank layer disposed between the light extraction structures, and a reflective layer disposed between the light extraction structures and the first bank layer and surrounding at least a side surface of each of the light extraction structures, each of the light emitting elements is covered by a corresponding light extraction structure among the light extraction structures, and the side surface of each of the light extraction structures includes a substantially inversely tapered inclined surface.

### CROSS-REFERENCE TO RELATED APPLICATION(S)

This application claims priority to and benefits of Korean Patent Application No. 10-2024-0025924 under 35 U.S.C. § 119, filed on Feb. 22, 2024 in the Korean Intellectual Property Office, the entire contents of which are incorporated herein by reference.

### BACKGROUND

### 1. Technical Field

The disclosure relates to a display device and a method of manufacturing the same.

### 2. Description of the Related Art

A display device may include pixels, and each of the pixels may emit light. The display device may display an image by combining the light emitted from the pixels.

Research for improving light output efficiency of the pixels included in the display device is being conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device with improved light output efficiency.

Another object of the disclosure is to provide a method of manufacturing the display device.

According to embodiments of the disclosure, a display device may include a plurality of light emitting elements disposed on a pixel circuit layer; a plurality of light extraction structures spaced apart from each other on the pixel circuit layer and overlapping the plurality of light emitting elements; a first bank layer disposed between the plurality of light extraction structures; and a reflective layer disposed between the plurality of light extraction structures and the first bank layer, the reflective layer surrounding at least a side surface of each of the plurality of light extraction structures, wherein each of the plurality of light emitting elements is covered by a corresponding light extraction structure among the plurality of light extraction structures, and the side surface of each of the plurality of light extraction structures may include a substantially inversely tapered inclined surface.

In an embodiment, each of the plurality of light extraction structures may include a negative photoresist material.

In an embodiment, the reflective layer may not be disposed between a lower surface of each of the plurality of light extraction structures and the pixel circuit layer.

In an embodiment, each of the plurality of light extraction structures may surround at least a portion of a side surface adjacent to an upper surface of a corresponding light emitting element among the plurality of light emitting elements.

In an embodiment, each of the plurality of light extraction structures may include a scattering particle.

In an embodiment, an upper edge of each of the plurality of light extraction structures may have a substantially rounded shape in cross-section.

In an embodiment, a side surface between a lower surface and an upper edge of each of the plurality of light extraction structures may be a substantially inversely tapered inclined surface in cross-section.

In an embodiment, the reflective layer may extend from the side surface of each of the plurality of light extraction structures to further cover the upper edge of each of the plurality of light extraction structures and a portion of an upper surface adjacent to the upper edge.

In an embodiment, the reflective layer may cover a lowermost surface of the first bank layer.

In an embodiment, a side surface of the reflective layer and a side surface of the first bank layer may be aligned with each other on the upper surface of each of the plurality of light extraction structures.

In an embodiment, the reflective layer may cover a portion of the upper edge adjacent to the side surface of each of the plurality of light extraction structures and may not cover an upper surface of each of the plurality of light extraction structures.

In an embodiment, a lowermost surface of the first bank layer may not be covered by the reflective layer.

In an embodiment, the display device may further include a plurality of light conversion patterns spaced apart from each other on the plurality of light extraction structures that overlap the plurality of light extraction structures.

In an embodiment, the display device may further include a second bank layer disposed overlapping the first bank layer to surround each of the plurality of light conversion patterns, and a light reflective layer disposed between the plurality of light conversion patterns and the second bank layer.

According to embodiments of the disclosure, a method of manufacturing a display device may include forming a plurality of light emitting elements on a pixel circuit layer; forming a plurality of light extraction structures spaced apart from each other on the pixel circuit layer that overlap the plurality of light emitting elements; forming a reflective layer entirely on the pixel circuit layer, the reflective layer covering the plurality of light extraction structures; forming a first bank layer entirely on the reflective layer, the first bank layer covering the reflective layer; etching the first bank layer disposed in an area overlapping at least a portion of an upper surface of each of the plurality of light extraction structures, and etching the reflective layer using the first bank layer as a mask, wherein each of the plurality of light emitting elements may be surrounded by a corresponding light extraction structure among the plurality of light extraction structures, and a side surface of each of the plurality of light extraction structures may include a substantially inversely tapered inclined surface.

In an embodiment, the forming of the plurality of light extraction structures may include forming an overcoating layer entirely on the pixel circuit layer, the overcoating layer covering the plurality of light emitting elements, and forming the plurality of light extraction structures by exposing and developing the overcoating layer.

In an embodiment, the overcoating layer may include a negative photoresist material.

According to embodiments of the disclosure, a method of manufacturing a display device may include forming a plurality of light emitting elements on a pixel circuit layer; forming a plurality of light extraction structures spaced apart from each other on the pixel circuit layer that overlap the plurality of light emitting elements; forming a reflective layer entirely on the pixel circuit layer, the reflective layer covering the plurality of light extraction structures; etching the reflective layer disposed in an area overlapping at least a portion of an upper surface of each of the plurality of light extraction structures; forming a first bank layer entirely on the pixel circuit layer, the first bank layer covering the plurality of light extraction structures and the reflective layer; and etching the first bank layer disposed in an area overlapping at least a portion of the upper surface of each of the plurality of light extraction structures, wherein each of the plurality of light emitting elements may be surrounded by a corresponding light extraction structure among the plurality of light extraction structures, and a side surface of each of the plurality of light extraction structures may include a substantially inversely tapered inclined surface.

In an embodiment, the etching of the reflective layer may include anisotropic dry etching the reflective layer.

In an embodiment, a portion of the reflective layer disposed between the plurality of light extraction structures may be etched in etching the reflective layer.

A display device according to embodiments of the disclosure may include a plurality of light extraction structures spaced apart from each other to overlap a plurality of light emitting elements, and a reflective layer surrounding at least a side surface of each of the plurality of light extraction structures. Each of the plurality of light emitting elements is covered by a corresponding light extraction structure among the plurality of light extraction structures, and the side surface of each of the plurality of light extraction structures may include a substantially inversely tapered inclined surface. Accordingly, light output efficiency of light emitted from the plurality of light emitting elements may be improved by the plurality of light extraction structures and the reflective layer.

A method of manufacturing a display device according to embodiments of the disclosure may provide an efficient method of manufacturing the display device described above.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating a display device according to embodiments of the disclosure;

FIG. 2 is a block diagram illustrating one sub-pixel among sub-pixels included in the display device of FIG. 1;

FIG. 3 is a schematic plan view illustrating a display panel configuring the display device of FIG. 1;

FIG. 4 is a schematic cross-sectional view illustrating an embodiment of the display panel of FIG. 3;

FIG. 5 is a schematic cross-sectional view illustrating an embodiment of the display panel of FIG. 3;

FIG. 6 is a schematic plan view illustrating an embodiment of one pixel among the pixels included in the display panel of FIG. 3;

FIGS. 7 and 8 are schematic cross-sectional views illustrating the pixel according to an embodiment of FIG. 6;

FIGS. 9 and 10 are schematic cross-sectional views illustrating a modified example of the pixel according to an embodiment of FIG. 6;

FIGS. 11 and 12 are schematic cross-sectional views illustrating a modified example of the pixel according to an embodiment of FIG. 6;

FIG. 13 is a schematic plan view illustrating a second embodiment of one pixel among of the pixels included in the display panel of FIG. 3;

FIG. 14 is a schematic cross-sectional view taken along line X2-X2′ of FIG. 13;

FIG. 15 is a schematic cross-sectional view taken along line Y2-Y2′ of FIG. 13;

FIG. 16 is a schematic plan view illustrating a third embodiment of one pixel among the pixels included in the display panel of FIG. 3;

FIG. 17 is a schematic cross-sectional view taken along line X3-X3′ of FIG. 16;

FIGS. 18 to 24 are diagrams illustrating a method of manufacturing a display device according to an embodiment of the disclosure;

FIGS. 25 to 28 are diagrams illustrating a method of manufacturing a display device according to an embodiment;

FIG. 29 is a block diagram illustrating a display system according to an embodiment; and

FIGS. 30 to 33 are schematic perspective views illustrating application examples of the display system of FIG. 29.

### DETAILED DESCRIPTION OF THE EMBODIMENTS

Hereinafter, embodiments according to the disclosure are described in detail with reference to the accompanying drawings. It should be noted that in the following description, portions desirable for understanding an operation according to the disclosure are described, and descriptions of other portions may be omitted in order not to obscure the subject matter of the disclosure. The disclosure may be embodied in other forms without being limited to the embodiments described herein. However, the embodiments described herein are provided to describe in detail to readily implement the technical spirit of the disclosure to those skilled in the art to which the disclosure pertains.

Throughout the specification, in a case where a portion is “connected” to another portion, the case includes not only a case where the portion is “directly connected” but also a case where the portion is “indirectly connected” with another element disposed therebetween. Terms used herein are for describing given embodiments and are not intended to limit the disclosure.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. The device may face in other directions (for example, rotated 90 degrees or in other directions) and thus the spatially relative terms used herein are interpreted according thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to illustrated shapes, and should be interpreted as including, for example, changes in shapes that occur as a result of manufacturing. As described above, the shapes shown in the drawings may not show actual shapes of areas of a device, and the embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

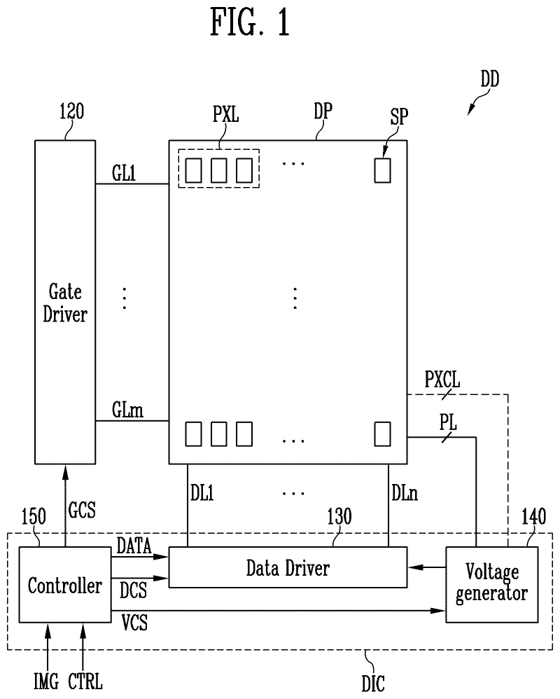

FIG. 1 is a block diagram illustrating a display device according to embodiments of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red, green, blue, cyan, magenta, or yellow.

Two or more sub-pixels among the sub-pixels SP may configure one pixel PXL. For example, the pixel PXL may include three sub-pixels as shown in FIG. 1. The pixel PXL may emit light of various colors and various luminances according to a combination of light emitted from the sub-pixels included in the pixel PXL.

The gate driver 120 is connected to the sub-pixels SP arranged (or disposed) in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like within the spirit and the scope of the disclosure.

The gate driver 120 may be disposed on one side or a side of the display panel DP. However, embodiments are not limited thereto. For example, the gate driver 120 may be divided into two or more physically and/or logically divided drivers, and such drivers may be disposed on one side or a side of the display panel DP and another side of the display panel DP opposite the one side or a side. As described above, the gate driver 120 may be disposed around the display panel DP in various shapes according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate voltages and provide the generated voltages to components of the display device DD, such as the gate driver 120, the data driver 130, and the controller 150. The voltage generator 140 may generate the voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In an embodiment, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a selectable reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, the pixel control lines PXCL are connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls overall operations of the display device DD. The controller 150 receives input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC.

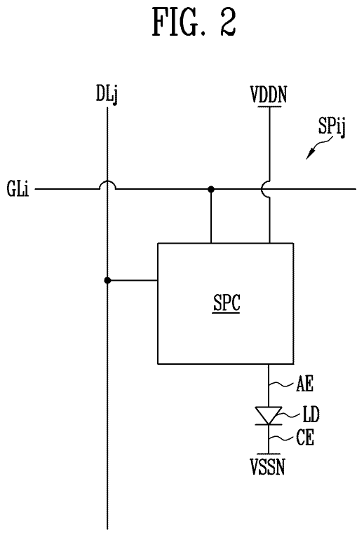

FIG. 2 is a block diagram illustrating one sub-pixel among the sub-pixels included in the display device of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN is connected to one of the power lines PL of FIG. 1 and receives the first power voltage. The second power voltage node VSSN is connected to another one of the power lines PL of FIG. 1 and receives the second power voltage. The first power voltage may have a voltage level higher than that of the second power voltage.

The light emitting element LD is connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, and the like within the spirit and the scope of the disclosure.

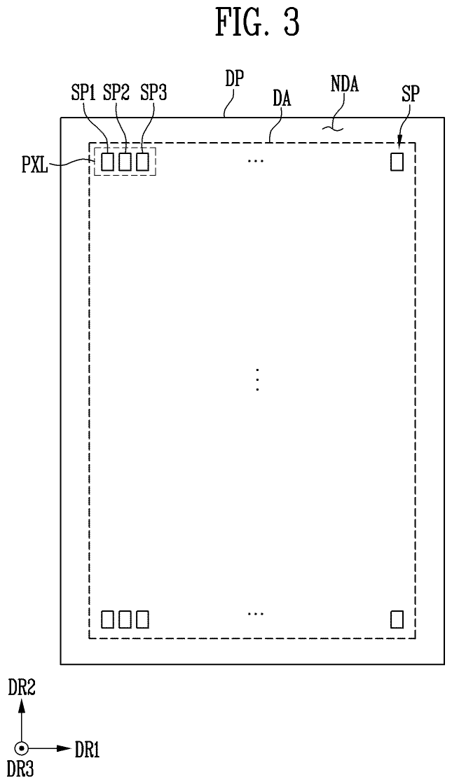

FIG. 3 is a schematic plan view illustrating the display panel configuring the display device of FIG. 1.

Referring to FIG. 3, the display panel DP may include a display area DA and a non-display area NDA. The display panel DP displays an image through the display area DA. The non-display area NDA is disposed around the display area DA.

The display panel DP may include the sub-pixels SP disposed in the display area DA. The sub-pixels SP may be arranged along a first direction DR1 and a second direction DR2 crossing (or intersecting) the first direction DR1. For example, the sub-pixels SP may be arranged in a matrix form along the first direction DR1 and the second direction DR2. As another example, the sub-pixels SP may be arranged in a zigzag form along the first direction DR1 and the second direction DR2. An arrangement of the sub-pixels SP may vary according to embodiments. The first direction DR1 may be a column direction, and the second direction DR2 may be a row direction.

Two or more sub-pixels among the sub-pixels SP may configure one pixel PXL. In FIG. 3, the pixel PXL may include three sub-pixels SP1, SP2, and SP3, but embodiments are not limited thereto. For example, the pixel PXL may include two sub-pixels. Hereinafter, for convenience of description, it is assumed that the pixel PXL may include the first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and concise description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1, SP2, and SP3 may include at least one light emitting element configured to generate light. In embodiments, the light emitting elements of the first to third sub-pixels SP1, SP2, and SP3 may generate light of the same color. For example, the light emitting elements of the first to third sub-pixels SP1, SP2, and SP3 may generate the light of the blue color. In other embodiments, the light emitting elements of the first to third sub-pixels SP1, SP2, and SP3 may generate light of different colors. For example, the light emitting elements of the first to third sub-pixels SP1, SP2, and SP3 may generate light of a red color, a green color, and a blue color, respectively.

As the display panel DP, a light emitting diode display panel (LED display panel) using a micro scale or nano scale of light emitting diode as a light emitting element, and a display panel capable of self-emission such as an organic light emitting display panel (OLED panel) using an organic light emitting diode as a light emitting element may be used.

A component for controlling the sub-pixels SP may be disposed in the non-display area NDA. Lines connected to the sub-pixels SP, for example, the first to m-th gate lines GL1 to GLm of FIG. 1, the first to n-th data lines DL1 to DLn, the power lines PL, and the pixel control lines PXCL may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. In this case, the data driver 130, the voltage generator 140, and the controller 150 may be implemented as a driver integrated circuit DIC of FIG. 1, separate from the display panel DP, and the driver integrated circuit DIC may be connected to the lines disposed in the non-display area NDA. In other embodiments, the gate driver 120 may be implemented as one integrated circuit separate from the display panel DP, together with the data driver 130, the voltage generator 140, and the controller 150.

In embodiments, the display area DA may have various shapes. The display area DA may have a closed loop shape including sides of a straight line and/or a curved line. For example, the display area DA may have shapes of a polygon, a circle, a semicircle, an ellipse, and the like within the spirit and the scope of the disclosure.

In embodiments, the display panel DP may have a flat display surface. In other embodiments, the display panel DP may have a display surface that is at least partially round. In embodiments, the display panel DP may be bendable, foldable, or rollable. In such cases, the display panel DP and/or a substrate of the display panel DP may include materials having a flexible property.

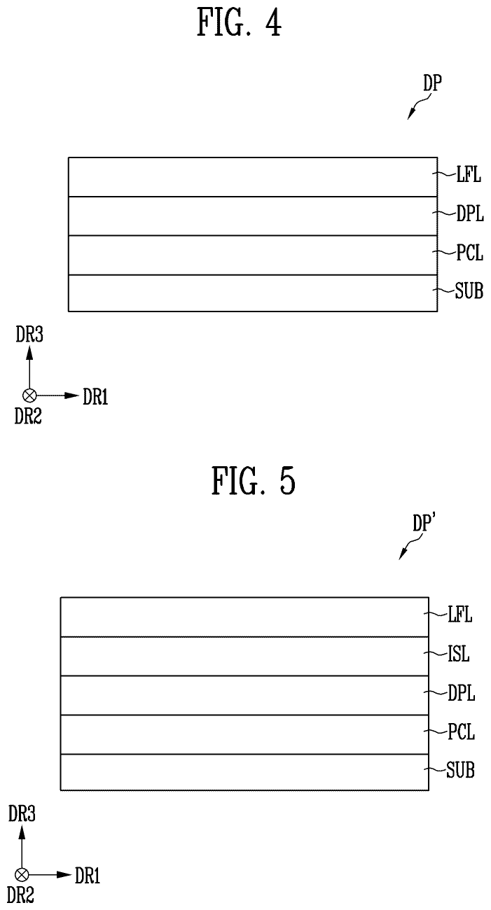

FIG. 4 is a schematic cross-sectional view illustrating an embodiment of the display panel of FIG. 3.

Referring to FIG. 4, the display panel DP may include a substrate SUB, and a pixel circuit layer PCL, a display element layer DPL, and a light functional layer LFL sequentially stacked each other on the substrate SUB in a third direction DR3 crossing (or intersecting) the first and second directions DR1 and DR2.

The substrate SUB may be formed of an insulating material such as glass or resin. For example, the substrate SUB may include a glass substrate. As another example, the substrate SUB may include a polyimide (PI) substrate. As another example, the substrate SUB may include a silicon wafer substrate formed using a semiconductor process.

In embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL is disposed on the substrate SUB. The pixel circuit layer PCL may include insulating layers and semiconductor patterns and conductive patterns disposed between the insulating layers. The conductive patterns of the pixel circuit layer PCL may function as circuit elements, lines, and the like within the spirit and the scope of the disclosure.

The circuit elements of the pixel circuit layer PCL may include the sub-pixel circuit SPC of FIG. 2 of each of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines to drive the display element layer DPL.

The display element layer DPL is disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In embodiments, the light conversion patterns and the light scattering patterns may be omitted.

The light functional layer LFL may further include a color filter layer including color filters. The color filter may selectively transmit light of a specific wavelength (or a specific color). In embodiments, the color filter layer may be omitted.

A window for protecting an exposure surface (or an upper surface) of the display panel DP may be provided on the light functional layer LFL. The window may protect the display panel DP from external shock. The window may be coupled or connected to the light functional layer LFL through an optically transparent adhesive (or cohesive) member. The window may have a multi-layer structure selected from a glass substrate, a plastic film, and a plastic substrate. The multi-layer structure may be formed through a continuous process or an adhesion process using an adhesive layer. All or a portion of the window may be flexible.

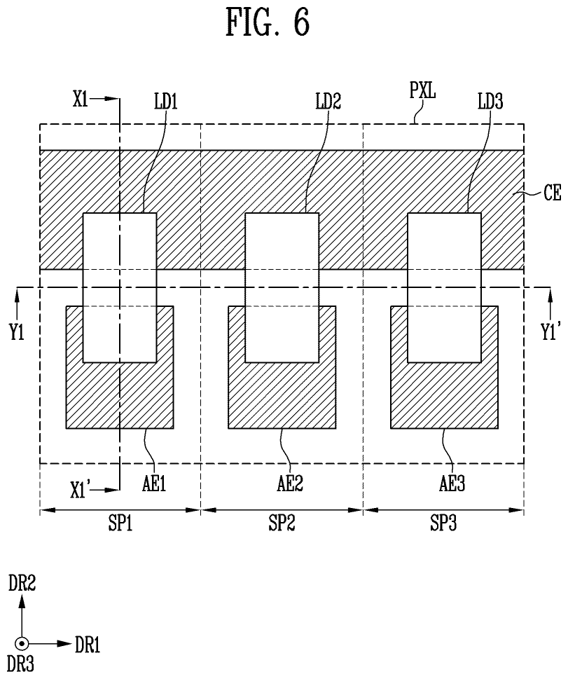

FIG. 5 is a schematic cross-sectional view illustrating an embodiment of the display panel of FIG. 3.

Referring to FIG. 5, the display panel DP′ may include the substrate SUB, the pixel circuit layer PCL, the display element layer DPL, an input sensing layer ISL, and the light functional layer LFL. The substrate SUB, the pixel circuit layer PCL, the display element layer DPL, and the light functional layer LFL may be configured equally (or similarly) to the substrate SUB, the pixel circuit layer PCL, the display element layer DPL, and the light functional layer LFL described with reference to FIG. 5. Therefore, a description of an overlapping content may be omitted.

The input sensing layer ISL may sense a user's input on an upper surface (or a display surface) of the display panel DP′. The input sensing layer ISL may include components suitable for sensing an external object such as a user's hand, or a pen. For example, the input sensing layer ISL may include touch electrodes.

FIG. 6 is a schematic plan view illustrating an embodiment of one pixel among the pixels included in the display panel of FIG. 3.

Referring to FIG. 6, the pixel PXL may include the first to third sub-pixels SP1, SP2, and SP3. The first to third sub-pixels SP1, SP2, and SP3 may be arranged in the first direction DR1. However, an arrangement of the pixel PXL is not limited thereto and may variously change according to embodiments. For example, the first to third sub-pixels SP1, SP2, and SP3 may be arranged in a zigzag.

First to third anode electrodes AE1, AE2, and AE3 may be disposed in the first to third sub-pixels SP1, SP2, and SP3, respectively. The first anode electrode AE1 may be provided as the anode electrode AE of FIG. 2 connected to the sub-pixel circuit SPC of FIG. 2 of the first sub-pixel SP1. The second anode electrode AE2 may be provided as the anode electrode AE connected to the sub-pixel circuit SPC of the second sub-pixel SP2. The third anode electrode AE3 may be provided as the anode electrode AE connected to the sub-pixel circuit SPC of the third sub-pixel SP3.

The cathode electrode CE may be spaced apart from the first to third anode electrodes AE1, AE2, and AE3. The cathode electrode CE may be disposed at the same height as the first to third anode electrodes AE1, AE2, and AE3. The cathode electrode CE may be spaced apart from the first to third anode electrodes AE1, AE2, and AE3 in the second direction DR2.

In embodiments, the cathode electrode CE may extend in the first direction DR1 and may be used as a common electrode for the pixel PXL and other pixels adjacent to the pixel PXL. Although not shown, the cathode electrode CE may extend not only in the first direction DR1 but also in the second direction DR2 and may be used as a common electrode for all of the sub-pixels SP of FIG. 3. As described above, the cathode electrode CE may have various shapes.

First to third light emitting elements LD1, LD2, and LD3 may be disposed on the first to third anode electrodes AE1, AE2, and AE3 and the cathode electrode CE. The first light emitting element LD1 may be electrically connected to the first anode electrode AE1 and the cathode electrode CE. The first light emitting element LD1 may be provided as the light emitting element LD of FIG. 2 connected to the sub-pixel circuit SPC of the first sub-pixel SP1. The second light emitting element LD2 may be electrically connected to the second anode electrode AE2 and the cathode electrode CE. The second light emitting element LD2 may be provided as the light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as the light emitting element LD connected to the sub-pixel circuit SPC of the third sub-pixel SP3.

The first light emitting element LD1, the second light emitting element LD2, and the third light emitting element LD3 may be inorganic light emitting diodes including an inorganic light emitting material. However, embodiments are not limited thereto, and for example, organic light emitting diodes may be used.

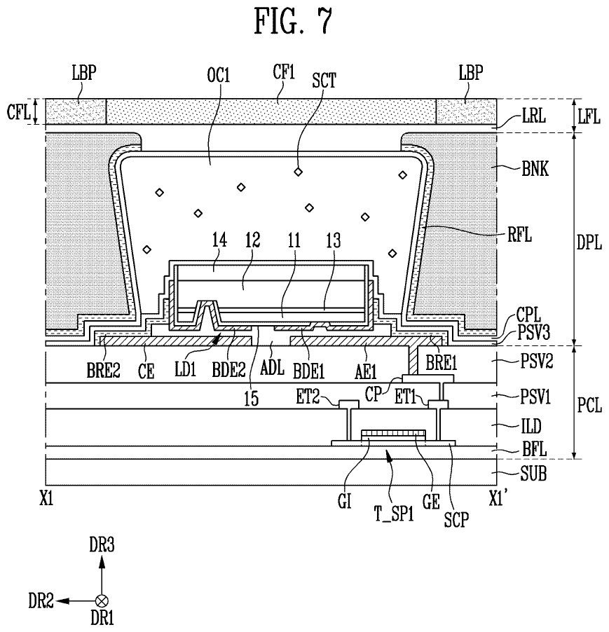

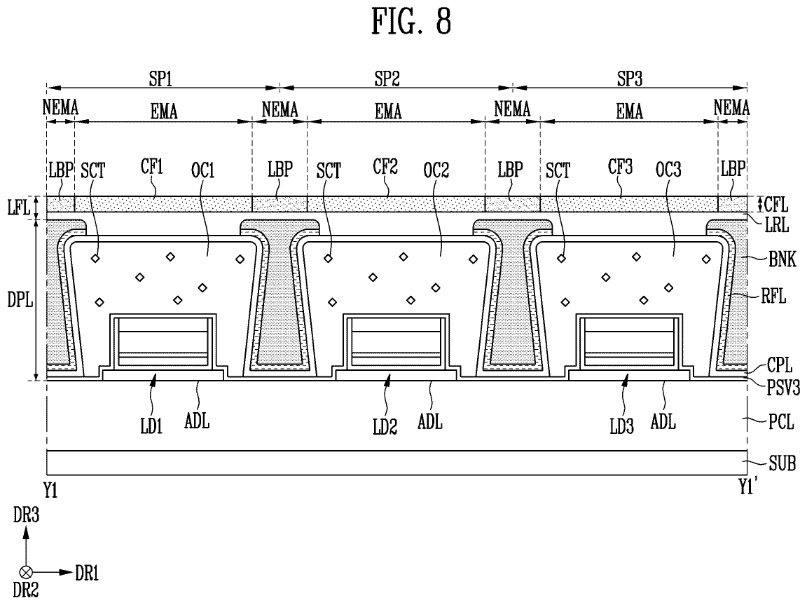

FIGS. 7 and 8 are schematic cross-sectional views illustrating the pixel according to an embodiment of FIG. 6. FIG. 7 is a schematic cross-sectional view taken along line X1-X1′ of FIG. 6, and FIG. 8 is a schematic cross-sectional view taken along line Y1-Y1′ of FIG. 6.

Referring to FIGS. 6 and 7, the pixel circuit layer PCL, the display element layer DPL, and the light functional layer LFL may be sequentially disposed on the substrate SUB.

The pixel circuit layer PCL may include insulating layers, semiconductor patterns, and conductive patterns stacked each other on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit SPC of FIG. 2 of each of the first to third sub-pixels SP1, SP2, and SP3 may include transistors and one or more capacitors. The semiconductor patterns and the conductive patterns of the pixel circuit layer PCL may function as the transistors and the capacitors of the sub-pixel circuit SPC. The conductive patterns of the pixel circuit layer PCL may further functions as the lines, for example, the first to m-th gate lines GL1 to GLm, the first to n-th data lines DL1 to DLn, the power lines PL, and the pixel control lines PXCL of FIG. 1.

The buffer layer BFL may be disposed on one surface or a surface of the substrate SUB. The buffer layer BFL may serve to prevent an impurity from diffusing into the circuit elements and the lines included in the pixel circuit layer PCL. The buffer layer BFL may include an inorganic insulating layer including an inorganic material. In embodiments, the buffer layer BFL may include at least one of metal oxides such as silicon nitride, silicon oxide, silicon oxynitride, and aluminum oxide. The buffer layer BFL may be provided as a single layer or multiple layers. In case that the buffer layer BFL is provided as the multiple layers, each layer may be formed of a same material or may be formed of different materials.

In embodiments, one or more barrier layers may be disposed between the substrate SUB and the buffer layer BFL. Each of the barrier layers may include polyimide.

A transistor T_SP1 may be disposed on the buffer layer BFL. The transistor T_SP1 may be one of the transistors of the sub-pixel circuit SPC included in the first sub-pixel SP1. For example, the transistor T_SP1 may be a transistor connected to the first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be the other one of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact area contacting the first terminal ET1 and a second contact area contacting the second terminal ET2. An area between the first contact area and the second contact area may be a channel area. The channel area may overlap the gate electrode GE of the transistor T_SP1. The channel area may be a semiconductor pattern that is not doped with an impurity and may be an intrinsic semiconductor. The first contact area and the second contact area may be a semiconductor pattern doped with an impurity. As the impurity, for example, a p-type impurity may be used, but embodiments are not limited thereto.

The semiconductor pattern SCP may include one of various types of semiconductors, for example, an amorphous silicon semiconductor, a monocrystalline silicon semiconductor, a polycrystalline silicon semiconductor, a low temperature poly silicon semiconductor, and an oxide semiconductor.

The interlayer insulating layers ILD sequentially stacked each other may be disposed on the semiconductor pattern SCP. The interlayer insulating layers ILD may be inorganic insulating layers including an inorganic material. For example, each of the interlayer insulating layers ILD may include at least one of metal oxides such as silicon nitride, silicon oxide, silicon oxynitride, and aluminum oxide. However, the interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the gate electrode GE is spaced apart from the semiconductor pattern SCP. In embodiments, the gate insulating layer GI may be provided entirely on the semiconductor pattern SCP and the buffer layer BFL to cover the semiconductor pattern SCP and the buffer layer BFL. As the number of layers required to form the conductive patterns and/or the semiconductor patterns increases, the number of interlayer insulating layers ILD may increase.

The gate electrode GE is disposed on the gate insulating layer GI. The gate electrode GE may overlap the channel area of the semiconductor pattern SCP. In embodiments, the gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as multiple layers including at least one material among molybdenum (Mo), titanium (Ti), copper (Cu), aluminum (Al), and silver (Ag), which are low-resistance materials.

The first and second terminals ET1 and ET2 are disposed on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are shown as separate electrodes electrically connected to the semiconductor pattern SCP, embodiments are not limited thereto. In embodiments, the first terminal ET1 may be a first contact area adjacent to one side or a side of the channel area of the semiconductor pattern SCP, and the second terminal ET2 may be a second contact area adjacent to another side of the channel area. In this case, the first terminal ET1 may be electrically connected to the light emitting element LD through a connection means such as a bridge electrode disposed on at least one of the interlayer insulating layers ILD.

In embodiments, the transistor T_SP1 may be configured of a low-temperature polysilicon transistor. However, embodiments are not limited thereto. For example, the transistor T_SP1 may be configured of an oxide semiconductor transistor. In embodiments, the sub-pixel circuit of the first sub-pixel SP1 may include different types of transistors. For example, the transistor T_SP1 may be configured of a low-temperature polysilicon transistor, and another transistor of the first sub-pixel SP1 may be configured of an oxide semiconductor transistor. In this case, the oxide semiconductor of the corresponding oxide semiconductor transistor may be disposed on one of the interlayer insulating layers ILD rather than the insulating layer on which the semiconductor pattern SCP of the transistor T_SP1 is disposed.

In embodiments, a case where the transistor T_SP1 is a transistor of a top gate structure is described as an example, but embodiments are not limited thereto. For example, the transistor T_SP1 may be a transistor of a bottom gate structure. A structure of the transistor T_SP1 may be variously changed.

At least some of the various lines of the display panel DP and/or the display device DD may be further disposed on the interlayer insulating layers ILD.

The first passivation layer PSV1 may be disposed on the interlayer insulating layers ILD and the first and second terminals ET1 and ET2. A passivation layer may be referred to as a protective layer or a via layer. The first passivation layer PSV1 may protect components disposed under (or below) the first passivation layer PSV1 and may provide a flat upper surface.

A connection electrode CP may be disposed on the first passivation layer PSV1. The connection electrode CP may be connected to the first terminal ET1 of the transistor T_SP1 by passing through the first passivation layer PSV1. The connection electrode CP may include at least one material among copper (Cu), molybdenum (Mo), tungsten (W), aluminum neodymium (AlNd), titanium (Ti), aluminum (Al), and silver (Ag).

At least some of the various lines of the display panel DP and/or the display device DD may be further disposed on the first passivation layer PSV1.

The second passivation layer PSV2 is disposed on the connection electrode CP and the first passivation layer PSV1. The second passivation layer PSV2 may protect components disposed under the second passivation layer PSV2 and may provide a flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as silicon oxide, silicon nitride, silicon oxynitride, and aluminum oxide. The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

The display element layer DPL may be disposed on the second passivation layer PSV2. The display element layer DPL may include the first anode electrode AE1, the cathode electrode CE, an adhesive layer ADL, first and second bridge electrodes BRE1 and BRE2, the first light emitting element LD1, a third passivation layer PSV3, a first light extraction structure OC1, a capping layer CPL, a reflective layer RFL, and a first bank layer BNK.

An electrode layer including the first anode electrode AE1 and the cathode electrode CE may be disposed on the pixel circuit layer PCL.

The first anode electrode AE1 may be electrically connected to the connection electrode CP through a contact hole passing through the second passivation layer PSV2. As described above, the first anode electrode AE1 may be electrically connected to the transistor T_SP1.

The cathode electrode CE may be spaced apart from the first anode electrode AE1 in the second direction DR2. The cathode electrode CE may be electrically connected to the second power voltage node VSSN of FIG. 2. Accordingly, the second power voltage applied to the second power voltage node VSSN may be transmitted to the cathode electrode CE.

The adhesive layer ADL may be disposed on the first anode electrode AE1, the cathode electrode CE, and the second passivation layer PSV2 between the first anode electrode AE1 and the cathode electrode CE. The adhesive layer ADL may include an insulating material having an adhesive property. The adhesive layer ADL may serve to fix the first light emitting element LD1 attached to the adhesive layer ADL.

The first light emitting element LD1 may include a light emitting stack including a first semiconductor layer 11, a second semiconductor layer 12 disposed on the first semiconductor layer 11, and an active layer 13 disposed between the first semiconductor layer 11 and the second semiconductor layer 12. In embodiments, the light emitting stack may further include an auxiliary layer 14 disposed on the second semiconductor layer 12.

The first semiconductor layer 11 provides a hole to the active layer 13. The first semiconductor layer 11 may include at least one p-type semiconductor layer. For example, the first semiconductor layer 11 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a p-type dopant such as magnesium (Mg), zinc (Zn), calcium (Ca), strontium (Sr), and barium (Ba). However, a material configuring the first semiconductor layer 11 is not limited thereto, and various other materials may configure the first semiconductor layer 11. In an embodiment, the first semiconductor layer 11 may include a gallium nitride (GaN) semiconductor material doped with the p-type dopant.

The second semiconductor layer 12 provides an electron to the active layer 13. The second semiconductor layer 12 may include at least one n-type semiconductor material. For example, the second semiconductor layer 12 may include at least one semiconductor material among gallium nitride (GaN), aluminum gallium nitride (AlGaN), indium gallium nitride (InGaN), aluminum nitride (AlN), and indium nitride (InN), and may be an n-type semiconductor layer doped with an n-type dopant such as silicon (Si), germanium (Ge), and tin (Sn). However, a material configuring the second semiconductor layer 12 is not limited thereto, and various other materials may configure the second semiconductor layer 12. In an embodiment, the second semiconductor layer 12 may include a gallium nitride (GaN) semiconductor material doped with the n-type dopant. According to an embodiment, the second semiconductor layer 12 may configure the n-type semiconductor layer together with the auxiliary layer 14.

The active layer 13 may be disposed between the first semiconductor layer 11 and the second semiconductor layer 12 and may be an area where the electron and the hole are recombined. As the electron and the hole recombine in the active layer 13, the electron and the hole may transit to a lower energy level, and thus light having a wavelength corresponding thereto may be generated. The active layer 13 may be formed as a single or multiple quantum wells structure. In case that the active layer 13 is formed as the multiple quantum wells structure, a unit including a barrier layer, a strain reinforcing layer, and a well layer may be repeatedly stacked each other to form the active layer 13. However, embodiments of the active layer 13 are not limited thereto.

The auxiliary layer 14 may include a gallium nitride (GaN) semiconductor material in which an impurity is not substantially doped or an impurity is doped with a relatively low concentration, and may configure the n-type semiconductor layer together with the second semiconductor layer 12.

The first light emitting element LD1 may include a first bonding electrode BDE1 and a second bonding electrode BDE2. The first bonding electrode BDE1 may be connected to a lower surface of the first semiconductor layer 11. The first bonding electrode BDE1 may not physically contact the second semiconductor layer 12 and the active layer 13. The second bonding electrode BDE2 may be connected to the second semiconductor layer 12 that does not overlap the first semiconductor layer 11 and the active layer 13. For example, the second bonding electrode BDE2 may be connected to the second semiconductor layer 12 exposed by removing the first semiconductor layer 11 and the active layer 13 by etching. The second bonding electrode BDE2 may not physically contact the first semiconductor layer 11, the active layer 13, and the first bonding electrode BDE1. The first light emitting element LD1 may be a flip chip type light emitting element. In embodiments, the first bonding electrode BDE1 and the second bonding electrode BDE2 may include a eutectic metal.

In an embodiment, the first bonding electrode BDE1 and the second bonding electrode BDE2 may include a material suitable for reflecting incident light. For example, the first bonding electrode BDE1 and the second bonding electrode BDE2 may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto. As the first bonding electrode BDE1 and the second bonding electrode BDE2 include a material suitable for reflecting light, light output efficiency of light generated in the active layer 13 may be further improved.

The first light emitting element LD1 may include an insulating layer 15 that covers at least a portion of an outer peripheral surface of the light emitting stack. For example, the insulating layer 15 may entirely cover another outer peripheral surface of the light emitting stack except for an upper surface. The insulating layer 15 may serve to prevent an electrical short circuit that may occur in case that the active layer 13 contacts a conductive material other than the first semiconductor layer 11 and the second semiconductor layer 12. The insulating layer 15 may serve to prevent an electrical short circuit that may occur in case that the second bonding electrode BDE2 contacts the first semiconductor layer 11 and the active layer 13. The insulating layer 15 may include a transparent insulating material. As shown in FIG. 7, a portion of the first bonding electrode BDE1 and a portion of the second bonding electrode BDE2 may be exposed without being covered by the insulating layer 15.

The first bonding electrode BDE1 may extend along the insulating layer 15 covering a side surface of the light emitting stack. An extended portion of the first bonding electrode BDE1 and an exposed portion of the first anode electrode AE1 on which the adhesive layer ADL is not disposed may be electrically connected to each other through the first bridge electrode BRE1. The second bonding electrode BDE2 may extend along the insulating layer 15 covering the side surface of the light emitting stack. An extended portion of the second bonding electrode BDE2 and an exposed portion of the cathode electrode CE on which the adhesive layer ADL is not disposed may be electrically connected to each other through the second bridge electrode BRE2. The first bridge electrode BRE1 and the second bridge electrode BRE2 may include a same material as one of the first anode electrode AE1, the cathode electrode CE, the first bonding electrode BDE1, and the second bonding electrode BDE2, but embodiments are not limited thereto.

The third passivation layer PSV3 entirely covering components such as the first bridge electrode BRE1, the second bridge electrode BRE2, and the first light emitting element LD1 is disposed on the pixel circuit layer PCL. The third passivation layer PSV3 may protect the components disposed under the third passivation layer PSV3. The third passivation layer PSV3 may include a same material as one of the first passivation layer PSV1, the second passivation layer PSV2, and the interlayer insulating layer ILD, but embodiments are not limited thereto. In embodiments, the third passivation layer PSV3 may not be disposed on an upper surface of the first light emitting element LD1. The third passivation layer PSV3 may be omitted.

The first light extraction structure OC1 is disposed to overlap the first light emitting element LD1. The first light extraction structure OC1 may cover the first light emitting element LD1. In embodiments, the first light extraction structure OC1 may surround at least a portion of a side surface adjacent to the upper surface of the first light emitting element LD1. The first light extraction structure OC1 may include a material with a relatively high light transmittance so as to transmit light generated in the first light emitting element LD1.

The capping layer CPL may entirely cover the first light extraction structure OC1 and the third passivation layer PSV3. The capping layer CPL may protect components under the capping layer CPL, such as the first light emitting element LD1, from external water, moisture, and the like within the spirit and the scope of the disclosure. The capping layer CPL may include at least one of a metal oxide such as silicon nitride, silicon oxide, silicon oxynitride, and aluminum oxide. However, a material of the capping layer CPL is not limited thereto. The capping layer CPL may be omitted.

The first bank layer BNK may be disposed between the first light extraction structure OC1 and second and third light extraction structures OC2 and OC3 of FIG. 8 to be described later. Accordingly, the first bank layer BNK may surround the first light extraction structure OC1 and the second and third light extraction structures OC2 and OC3 to be described later. The first bank layer BNK may be configured to include a light blocking material, thereby preventing light mixing between adjacent sub-pixels. In embodiments, the first bank layer BNK may include an organic material. For example, the first bank layer BNK may include an organic insulating material such as acryl resin, epoxy resin, phenol resin, polyamide resin, and polyimide resin.

The reflective layer RFL is disposed between the first bank layer BNK and the first light extraction structure OC1. The reflective layer RFL may surround at least a side surface of the first light extraction structure OC1. The reflective layer RFL may include a material suitable for reflecting light. The reflective layer RFL may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The first light extraction structure OC1 and the reflective layer RFL may serve to improve light output efficiency of the light generated in the first light emitting element LD1. More specifically, a side surface of the first light extraction structure OC1 may include an inversely tapered inclined surface. For example, as shown in FIG. 7, the first light extraction structure OC1 may have a shape substantially identical (or similar) to a trapezoidal shape in which a length of an upper side is longer than a length of a lower side in cross-section. Here, the reflective layer RFL surrounding the side surface of the first light extraction structure OC1 may also have an inversely tapered shape corresponding to the shape of the side surface of the first light extraction structure OC1. Accordingly, the light generated in the first light emitting element LD1 may be reflected to proceed in a front surface direction (for example, the third direction DR3 and a direction crossing (or intersecting) thereto), thereby improving light output efficiency.

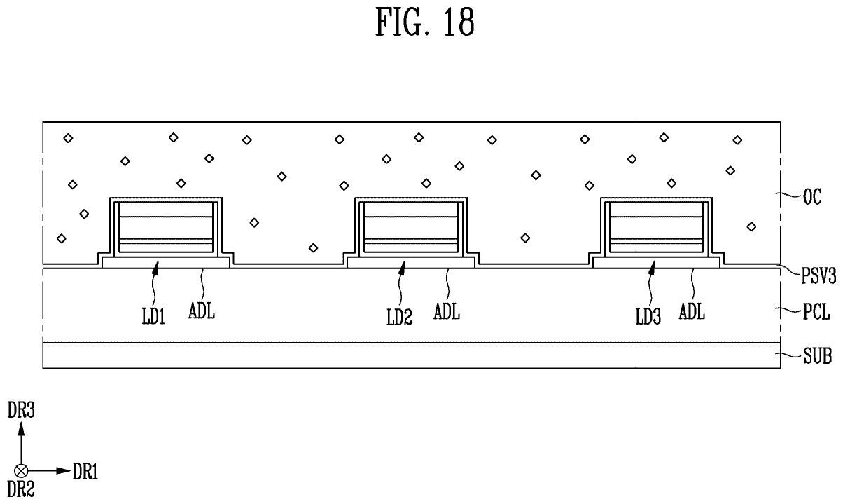

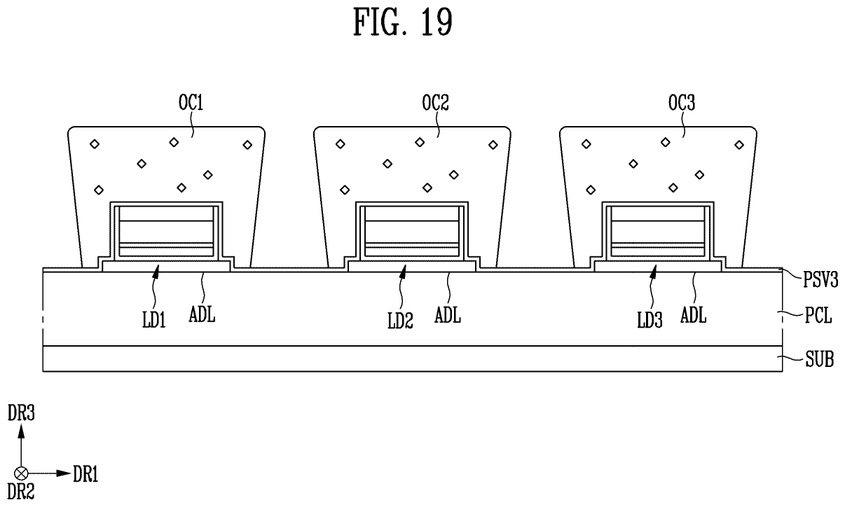

In an embodiment, the first light extraction structure OC1 may include a negative photoresist material. Accordingly, the first light extraction structure OC1 may be formed to have the side surface including the inversely tapered inclined surface. This is described in detail later with reference to FIGS. 18 and 19.

In an embodiment, the first light extraction structure OC1 may include a scattering particle SCT. The scattering particle SCT may scatter the light generated in the first light emitting element LD1. Accordingly, light output efficiency may be further improved.

In an embodiment, an upper edge of the first light extraction structure OC1 may have a rounded shape. In this case, a side surface between a lower surface and the upper edge of the first light extraction structure OC1 may be an inversely tapered inclined surface.

In an embodiment, the reflective layer RFL may extend from the side surface of the first light extraction structure OC1 to further cover the upper edge of the first light extraction structure OC1 and a portion of an upper surface adjacent to the upper edge. In this case, on the upper surface of the first light extraction structure OC1, the side surface of the reflective layer RFL and a side surface of the first bank layer BNK may be aligned with each other. As described above, as the upper edge of the first light extraction structure OC1 and a portion of the upper surface adjacent to the upper edge are covered by the reflective layer RFL and the first bank layer BNK, light mixing between adjacent sub-pixels may be further effectively prevented.

In the above-described embodiment, another portion of the upper surface of the first light extraction structure OC1 may not be covered by the reflective layer RFL and the first bank layer BNK. Accordingly, the light generated in the first light emitting element LD1 may be normally emitted through another portion of the upper surface of the first light extraction structure OC1 that is not covered by the reflective layer RFL and the first bank layer BNK.

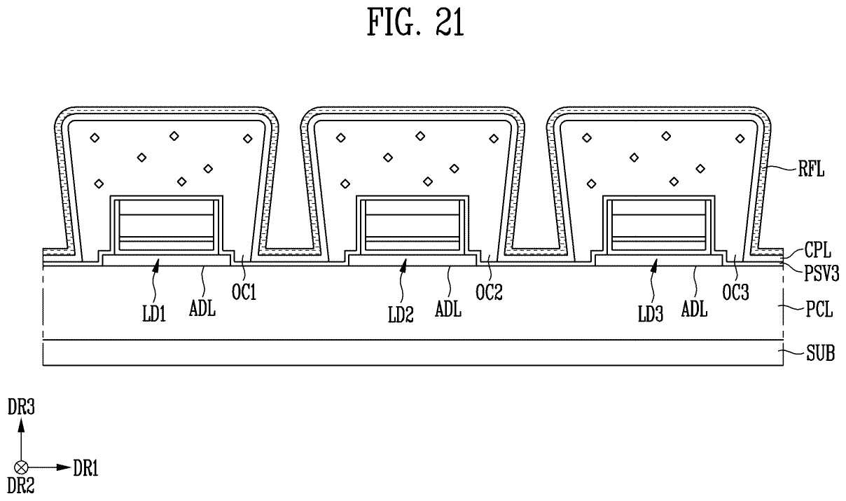

In an embodiment, the reflective layer RFL may cover the lowermost surface of the first bank layer BNK. This may be a structure by the manufacturing method of the disclosure in which the reflective layer RFL is formed through an etching process using the first bank layer BNK as a mask. This is described in detail later with reference to FIGS. 21 to 24.

In an embodiment, the reflective layer RFL may not be disposed between the lower surface of the first light extraction structure OC1 and the pixel circuit layer PCL. For example, the reflective layer RFL may not be disposed between the first light extraction structure OC1 and a component disposed immediately under the first light extraction structure OC1 (for example, the third passivation layer PSV3, or the first light emitting element LD1, the first bridge electrode BRE1, and the second bridge electrode BRE2 in case that the third passivation layer PSV3 may be omitted). This may be a structure appearing by the manufacturing method of the disclosure in which the reflective layer RFL is formed after forming the first light extraction structure OC1. This is described in detail later with reference to FIGS. 19 to 21.

Above, the pixel circuit layer PCL and the display element layer DPL of the first sub-pixel SP1 are described. Each of the second and third sub-pixels SP2 and SP3 of FIG. 6 may be configured similarly to the first sub-pixel SP1, unless otherwise described herein.

The light functional layer LFL is provided on the first bank layer BNK and the capping layer CPL. The light functional layer LFL may include a filling layer LRL and a color filter layer CFL.

The filling layer LRL is disposed on the first bank layer BNK and the capping layer CPL. The filling layer LRL may include a material with a relatively high light transmittance. The filling layer LRL may provide a flat upper surface. The filling layer LRL may be omitted.

The color filter layer CFL is disposed on the filling layer LRL. The color filter layer CFL may include a first color filter CF1 and light blocking patterns LBP. The first color filter CF1 overlaps the first light extraction structure OC1. The first color filter CF1 may selectively transmit light of a desired wavelength range. In case that the first sub-pixel SP1 is a red sub-pixel, the first color filter CF1 may include a red color filter. The light blocking patterns LBP may include at least one of various types of light blocking materials.

Referring to FIGS. 6 and 8, the pixel circuit layer PCL, the display element layer DPL, and the light functional layer LFL may be sequentially provided on the substrate SUB.

The pixel circuit layer PCL is described similarly to that described with reference to FIG. 7. In the pixel circuit layer PCL, sub-pixel circuits respectively corresponding to the first to third sub-pixels SP1, SP2, and SP3 are provided.

The display element layer DPL is described similarly to that described with reference to FIG. 7. In the display element layer DPL, the first to third light emitting elements LD1, LD2, and LD3 respectively correspond to the first to third sub-pixels SP1, SP2, and SP3 are provided. The first light emitting element LD1 is connected between the cathode electrode CE of FIG. 7 and the transistor T_SP1 of FIG. 7 included in the sub-pixel circuit of the first sub-pixel SP1. The second light emitting element LD2 is connected between the cathode electrode CE and the transistor included in the sub-pixel circuit of the second sub-pixel SP2. The third light emitting element LD3 is connected between the cathode electrode CE and the transistor included in the sub-pixel circuit of the third sub-pixel SP3.

In embodiments, in case that the first sub-pixel SP1 is a red sub-pixel, the first light emitting element LD1 may be configured to emit red color light. In case that the second sub-pixel SP2 is a green sub-pixel, the second light emitting element LD2 may be configured to emit green color light. In case that the third sub-pixel SP3 is a blue sub-pixel, the third light emitting element LD3 may be configured to emit blue color light. As described above, each of the first to third light emitting elements LD1, LD2, and LD3 may be configured to emit light of a color corresponding to a type of a corresponding sub-pixel.

First to third light extraction structures OC1, OC2, and OC3 respectively correspond to the first to third light emitting elements LD1, LD2, and LD3 are provided. The first to third light extraction structures OC1, OC2, and OC3 may be disposed to be spaced apart from each other. The first light extraction structure OC1 may cover the first light emitting element LD1. The second light extraction structure OC2 may cover the second light emitting element LD2. The third light extraction structure OC3 may cover the third light emitting element LD3. A side surface of each of the first to third light extraction structures OC1, OC2, and OC3 may include an inversely tapered inclined surface.

The first bank layer BNK is provided between the first to third light extraction structures OC1, OC2, and OC3. Accordingly, the first bank layer BNK may surround the first to third light extraction structures OC1, OC2, and OC3.

The reflective layer RFL is disposed between the first to third light extraction structures OC1, OC2, and OC3 and the first bank layer BNK. The reflective layer RFL may surround at least a side surface of each of the first to third light extraction structures OC1, OC2, and OC3.

In an embodiment, the reflective layer RFL may cover the lowermost surface of the first bank layer BNK. That is, the reflective layer RFL may extend from the side surface of the first to third light extraction structures OC1, OC2, and OC3 and may be disposed between the lowermost surface of the first bank layer BNK and the capping layer CPL (between the lowermost surface of the first bank layer BNK and the third passivation layer PSV3 in case that the capping layer CPL may be omitted).

The light functional layer LFL is provided on the display element layer DPL. The light functional layer LFL is described similarly to that described with reference to FIG. 7.

The filling layer LRL is disposed on the first bank layer BNK and the capping layer CPL. In embodiments, the filling layer LRL may be omitted in an area corresponding to the third sub-pixel SP3.

The color filter layer CFL is disposed on the filling layer LRL. The color filter layer CFL may include the first to third color filters CF1, CF2, and CF3, and the light blocking patterns LBP.

Each of the first to third color filters CF1, CF2, and CF3 may selectively transmit light of a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter.

The light blocking patterns LBP are disposed between the first to third color filters CF1, CF2, and CF3. It may be understood that an emission area (or a light output area) EMA and a non-emission area NEMA for the first to third sub-pixels SP1, SP2, and SP3 are defined by the light blocking patterns LBP. An area overlapping the light blocking patterns LBP may correspond to the non-emission area NEMA. An area that does not overlap the light blocking patterns LBP may correspond to the emission area EMA.

The light blocking patterns LBP may overlap the first bank layer BNK. The first to third color filters CF1, CF2, and CF3 may overlap the first to third light extraction structures OC1, OC2, and OC3. For example, the first color filter CF1 may overlap the first light extraction structure OC1, the second color filter CF2 may overlap the second light extraction structure OC2, and the third color filter CF3 may overlap the third light extraction structure OC3.

In embodiments, the light blocking patterns LBP may include at least one of various types of light blocking materials. In embodiments, each of the light blocking patterns LBP may be provided in a form of multiple layers in which at least two color filters among the first to third color filters CF1, CF2, and CF3 overlap. For example, each of the light blocking patterns LBP may be formed by overlapping the first to third color filters CF1, CF2, and CF3. As another example, a light blocking pattern between the first and second color filters CF1 and CF2 among the light blocking patterns LBP may be formed as multiple layers in which the first and second color filters CF1 and CF2 overlap, and a light blocking pattern between the second and third color filters CF2 and CF3 among the light blocking patterns LBP may be formed as multiple layers in which the second and third color filters CF2 and CF3 overlap. A light blocking pattern between the first color filter CF1 and the third color filter CF3 of a neighboring pixel may be formed as multiple layers in which the first and third color filters CF1 and CF3 overlap. As described above, each of the first to third color filters CF1, CF2, and CF3 may extend to the non-emission area NEMA to form the light blocking patterns LBP.

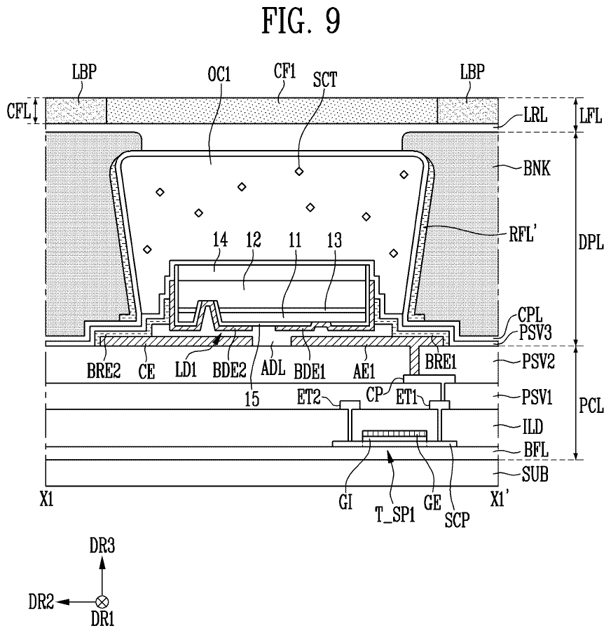

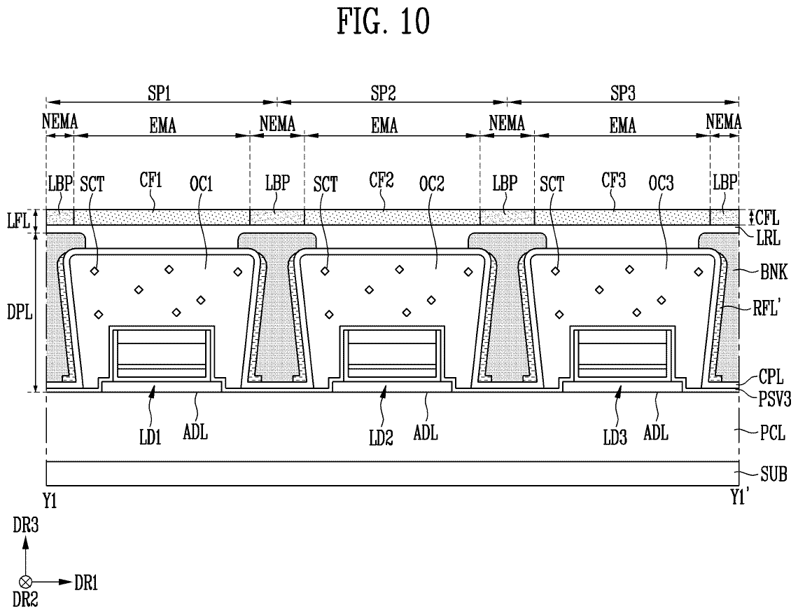

FIGS. 9 and 10 are schematic cross-sectional views illustrating a modified example of the pixel according to an embodiment of FIG. 6. FIG. 9 is a schematic cross-sectional view taken along line X1-X1′ of FIG. 6, and FIG. 10 is a schematic cross-sectional view taken along line Y1-Y1′ of FIG. 6.

As described above with reference to FIGS. 7 and 8, the reflective layer RFL of FIGS. 7 and 8 may be provided. Here, the pixels shown in FIGS. 9 and 10 may be substantially the same as the pixel described with reference to FIGS. 7 and 8, except for a shape of a reflective layer RFL′. Therefore, a description of an overlapping content may be omitted.

Referring to FIGS. 6, 9, and 10, the reflective layer RFL′ may cover a portion of an upper edge adjacent to the side surface of each of the first to third light extraction structures OC1, OC2, and OC3. In this case, another portion of the upper edge of each of the first to third light extraction structures OC1, OC2, and OC3 and an upper surface of each of the first to third light extraction structures OC1, OC2, and OC3 may not be covered by the reflective layer RFL′.

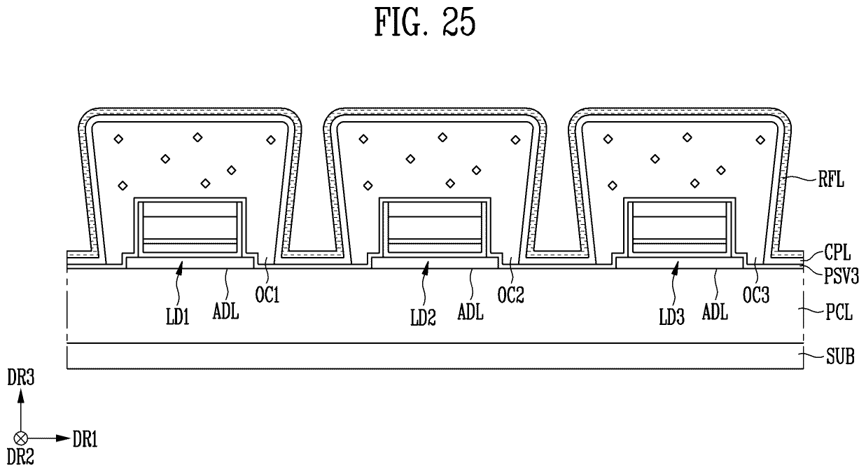

In this case, the lowermost surface of the first bank layer BNK may not be covered by the reflective layer RFL′. This may be a structure appearing by the manufacturing method of the disclosure in which the reflective layer RFL′ is formed before the first bank layer BNK is formed. This is described in detail later with reference to FIGS. 25 to 28.

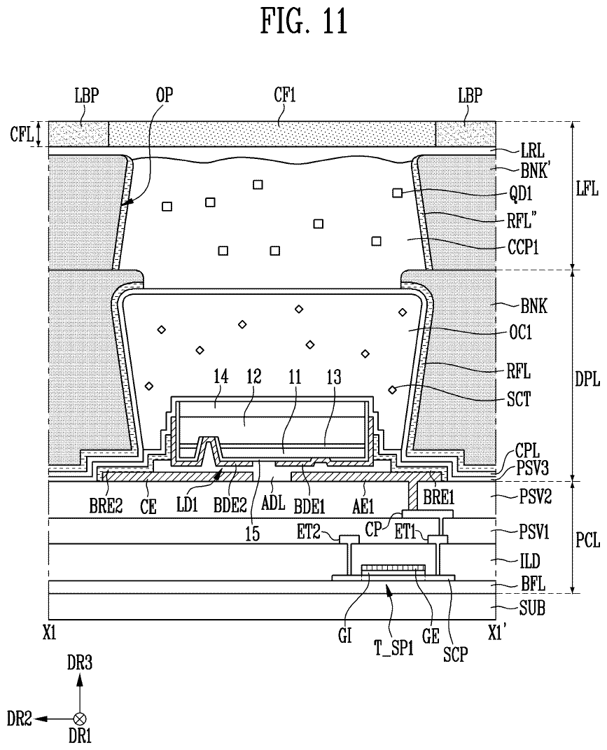

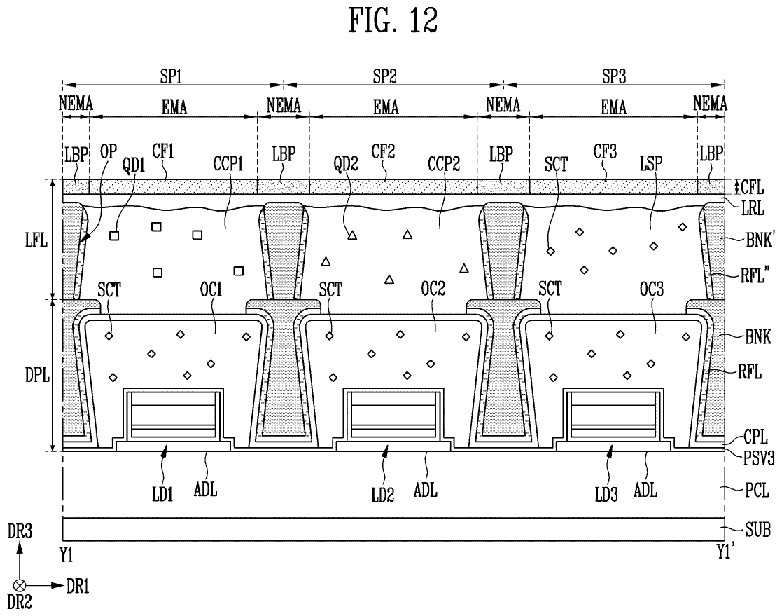

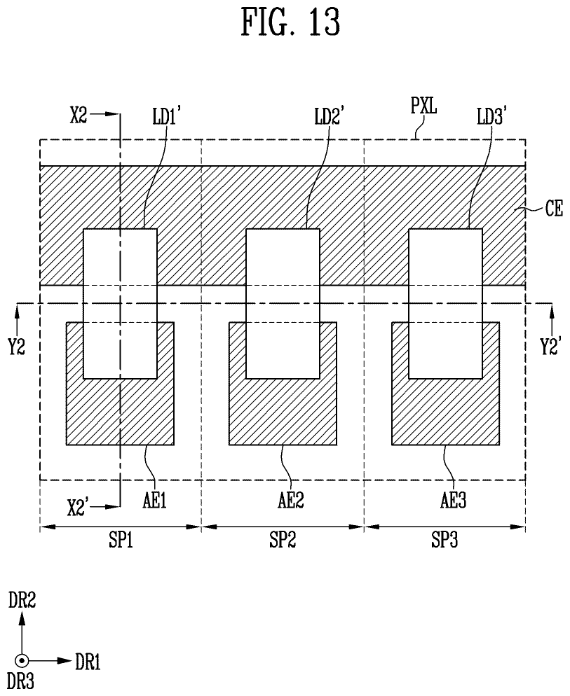

FIGS. 11 and 12 are schematic cross-sectional views illustrating a modified example of the pixel according to an embodiment of FIG. 6. FIG. 11 is a schematic cross-sectional view taken along line X1-X1′ of FIG. 6, and FIG. 12 is a schematic cross-sectional view taken along line Y1-Y1′ of FIG. 6.

Referring to FIGS. 6 and 11, the pixel circuit layer PCL, the display element layer DPL, and the light functional layer LFL may be sequentially disposed on the substrate SUB.

The pixel circuit layer PCL is described similarly to that described with reference to FIG. 7. Therefore, a description of an overlapping content may be omitted.

The display element layer DPL is described similarly to that described with reference to FIG. 7. Therefore, a description of an overlapping content may be omitted.

The light functional layer LFL is provided on the first bank layer BNK and the capping layer CPL. The light functional layer LFL may include a second bank layer BNK′, a light reflective layer RFL″, a first light conversion pattern CCP1, the filling layer LRL, and the color filter layer CFL.

The second bank layer BNK′ is disposed on the first bank layer BNK to overlap the first bank layer BNK. The second bank layer BNK′ may have an opening OP that overlaps the first light extraction structure OC1. The second bank layer BNK′ is configured to include a light blocking material, thereby preventing light mixing between adjacent sub-pixels. In embodiments, the second bank layer BNK′ may include an organic material. For example, the second bank layer BNK′ may include an organic insulating material such as acryl resin, epoxy resin, phenol resin, polyamide resin, and polyimide resin.

The light reflective layer RFL″ is disposed on side surfaces of the second bank layer BNK′ adjacent to the opening OP. The light reflective layer RFL″ is configured to reflect incident light, and thus light output efficiency may be improved. The reflective layer RFL″ may include a material suitable for reflecting light. The reflective layer RFL″ may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The first light conversion pattern CCP1 is disposed on the first light extraction structure OC1 to overlap the first light extraction structure OC1. The first light conversion pattern CCP1 is disposed in the opening OP. The first light conversion pattern CCP1 may include color conversion particles and/or scattering particles. The color conversion particles may change a wavelength of incident light and convert the incident light into light of a different color. The color conversion particles may scatter the incident light. In embodiments, the color conversion particles may be quantum dots.

In case that the first sub-pixel SP1 is a red sub-pixel, the first light emitting element LD1 may emit light of a color different from red. For example, the first light emitting element LD1 may emit blue color light. In this case, the first light conversion pattern CCP1 may include first color conversion particles QD1 configured to convert blue color light into red color light.

The filling layer LRL is disposed on the second bank layer BNK′ and the first light conversion pattern CCP1. The filling layer LRL may include a material with a relatively high light transmittance. The filling layer LRL may provide a flat upper surface. In embodiments, the filling layer LRL may have a refractive index lower than that of the first light conversion pattern CCP1. The filling layer LRL is configured to refract or totally reflect corresponding light according to an incidence angle. For example, the filling layer LRL may provide light passing through the first light conversion pattern CCP1 back to the first light conversion pattern CCP1. Accordingly, light conversion efficiency of the first light conversion pattern CCP1 may be improved. The filling layer LRL may be omitted.

The color filter layer CFL is disposed on the filling layer LRL. The color filter layer CFL may include a first color filter CF1 and light blocking patterns LBP. The first color filter CF1 overlaps the first light conversion pattern CCP1. The first color filter CF1 may selectively transmit light of a desired wavelength range. In case that the first sub-pixel SP1 is a red sub-pixel, the first color filter CF1 may include a red color filter. The light blocking patterns LBP may include at least one of various types of light blocking materials.

Referring to FIGS. 6 and 12, the pixel circuit layer PCL, the display element layer DPL, and the light functional layer LFL may be sequentially provided on the substrate SUB.

The pixel circuit layer PCL is described similarly to that described with reference to FIG. 7. In the pixel circuit layer PCL, the sub-pixel circuits corresponding to the first to third sub-pixels SP1, SP2, and SP3 are provided.

The display element layer DPL is described similarly to that described with reference to FIG. 7, except for a color of light emitted from each of the first to third light emitting elements LD1, LD2, and LD3. The first to third light emitting elements LD1, LD2, and LD3 shown in FIG. 12 may emit light of the same color. For example, the first to third light emitting elements LD1, LD2, and LD3 may generate blue color light.

The light functional layer LFL is provided on the display element layer DPL. The light functional layer LFL is described similarly to that described with reference to FIG. 11.

The second bank layer BNK′ is disposed on the first bank layer BNK to overlap the first bank layer BNK. The second bank layer BNK′ may have openings OP that overlap the first to third light extraction structures OC1, OC2, and OC3. First and second light conversion patterns CCP1 and CCP2 and the light scattering pattern LSP are disposed in the openings OP to overlap the first to third light extraction structures OC1, OC2, and OC3. The first light conversion pattern CCP1 is disposed on the first light extraction structure OC1. The second light conversion pattern CCP2 is disposed on the second light extraction structure OC2. The light scattering pattern LSP is disposed on the third light extraction structure OC3. The first and second light conversion patterns CCP1 and CCP2 and the light scattering pattern LSP may be disposed to be spaced apart from each other.

A light reflective layer RFL″ is disposed on side surfaces of the second bank layer BNK′ adjacent to the openings OP. Here, the light reflective layer RFL″ may be disposed between the first and second light conversion patterns CCP1 and CCP2 and the second bank layer BNK′ surrounding the first and second light conversion patterns CCP1 and CCP2, and between the light scattering pattern LSP and the second bank layer BNK′ surrounding the light scattering pattern LSP.

In embodiments, the first sub-pixel SP1 may be a red sub-pixel, the second sub-pixel SP2 may be a green sub-pixel, and the third sub-pixel SP3 may be a blue sub-pixel. The first to third light emitting elements LD1, LD2, and LD3 may be configured to emit blue light. In this case, the first light conversion pattern CCP1 may include first color conversion particles QD1 configured to convert blue color light into red color light. The second light conversion pattern CCP2 may include second color conversion particles QD2 configured to convert blue color light into green color light. The light scattering pattern LSP may include scattering particles SCT that scatter blue color light to improve light output efficiency. Accordingly, the first to third sub-pixels SP1, SP2, and SP3 may be provided as the red sub-pixel, the green sub-pixel, and the blue sub-pixel, respectively. In embodiments, at least one of the first and second light conversion patterns CCP1 the CCP2 and the light scattering pattern LSP may further include color conversion particles that convert blue color light into white color light.

The filling layer LRL may be disposed on the second bank layer BNK′, the first and second light conversion patterns CCP1 and CCP2, and the light scattering pattern LSP. In embodiments, the filling layer LRL may be omitted in an area corresponding to the third sub-pixel SP3.

The color filter layer CFL may be disposed on the filling layer LRL. The color filter layer CFL may include the first to third color filters CF1, CF2, and CF3, and the light blocking patterns LBP.

Each of the first to third color filters CF1, CF2, and CF3 may selectively transmit light of a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter.

The light blocking patterns LBP may be disposed between the first to third color filters CF1, CF2, and CF3. It may be understood that the emission area (or a light output area) EMA and the non-emission area NEMA for the first to third sub-pixels SP1, SP2, and SP3 are defined by the light blocking patterns LBP. An area overlapping the light blocking patterns LBP may correspond to the non-emission area NEMA. An area that does not overlap the light blocking patterns LBP may correspond to the emission area EMA.

The light blocking patterns LBP may overlap the second bank layer BNK′. The first to third color filters CF1, CF2, and CF3 may overlap the first and second light conversion patterns CCP1 and CCP2 and the light scattering pattern LSP. For example, the first color filter CF1 may overlap the first light conversion pattern CCP1, the second color filter CF2 may overlap the second light conversion pattern CCP2, and the third color filter CF3 may overlap the light scattering pattern LSP.

In embodiments, the light blocking patterns LBP may include at least one of various types of light blocking materials. In embodiments, each of the light blocking patterns LBP may be provided in a form of multiple layers in which at least two color filters among the first to third color filters CF1, CF2, and CF3 overlap. For example, each of the light blocking patterns LBP may be formed by overlapping the first to third color filters CF1, CF2, and CF3. As another example, a light blocking pattern between the first and second color filters CF1 and CF2 among the light blocking patterns LBP may be formed as multiple layers in which the first and second color filters CF1 and CF2 overlap, and a light blocking pattern between the second and third color filters CF2 and CF3 among the light blocking patterns LBP may be formed as multiple layers in which the second and third color filters CF2 and CF3 overlap. A light blocking pattern between the first color filter CF1 and the third color filter CF3 of a neighboring pixel may be formed as multiple layers in which the first and third color filters CF1 and CF3 overlap. As described above, each of the first to third color filters CF1, CF2, and CF3 may extend to the non-emission area NEMA to form the light blocking patterns LBP.

In FIGS. 11 and 12, the pixel is shown as including the reflective layer RFL described with reference to FIGS. 7 and 8, but the pixel of FIGS. 11 and 12 may include the reflective layer RFL′ described with reference to FIGS. 9 and 10.

FIG. 13 is a schematic plan view illustrating a second embodiment of one pixel among of the pixels included in the display panel of FIG. 3.

Referring to FIG. 13, the pixel PXL may include the first to third sub-pixels SP1, SP2, and SP3. The first to third sub-pixels SP1, SP2, and SP3 are described similarly to those described with reference to FIG. 6. Therefore, a description of an overlapping content may be omitted.

The first to third anode electrodes AE1, AE2, and AE3 and the cathode electrode CE are described similarly to those described with reference to FIG. 6. The first to third anode electrodes AE1, AE2, and AE3 may be disposed in the first to third sub-pixels SP1, SP2, and SP3, respectively. The cathode electrode CE may be spaced apart from the first to third anode electrodes AE1, AE2, and AE3. Hereinafter, a description of an overlapping content may be omitted.

First to third light emitting elements LD1′, LD2′, and LD3′ may be disposed on the first to third anode electrodes AE1, AE2, and AE3 and the cathode electrode CE. The first light emitting element LD1′ may be electrically connected to the first anode electrode AE1 and the cathode electrode CE. The first light emitting element LD1′ may be provided as the light emitting element LD of FIG. 2 connected to the sub-pixel circuit SPC of FIG. 2 of the first sub-pixel SP1. The second light emitting element LD2′ may be electrically connected to the second anode electrode AE2 and the cathode electrode CE. The second light emitting element LD2′ may be provided as the light emitting element LD of FIG. 2 connected to the sub-pixel circuit SPC of FIG. 2 of the second sub-pixel SP2. The third light emitting element LD3′ may be electrically connected to the third anode electrode AE3 and the cathode electrode CE. The third light emitting element LD3′ may be provided as the light emitting element LD of FIG. 2 connected to the sub-pixel circuit SPC of FIG. 2 of the third sub-pixel SP3.

The first light emitting element LD1′, the second light emitting element LD2′, and the third light emitting element LD3′ may be inorganic light emitting diodes including an inorganic light emitting material. However, embodiments are not limited thereto, and for example, the first light emitting element LD1′, the second light emitting element LD2′, and the third light emitting element LD3′ may be organic light emitting diodes including an organic light emitting material.

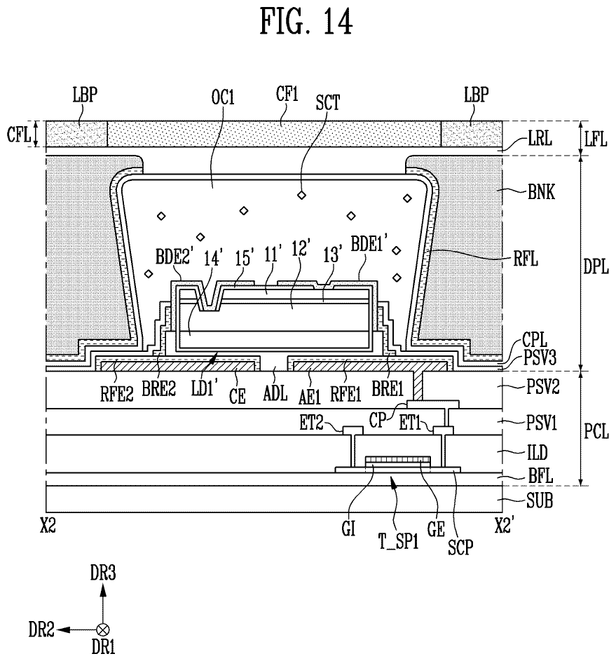

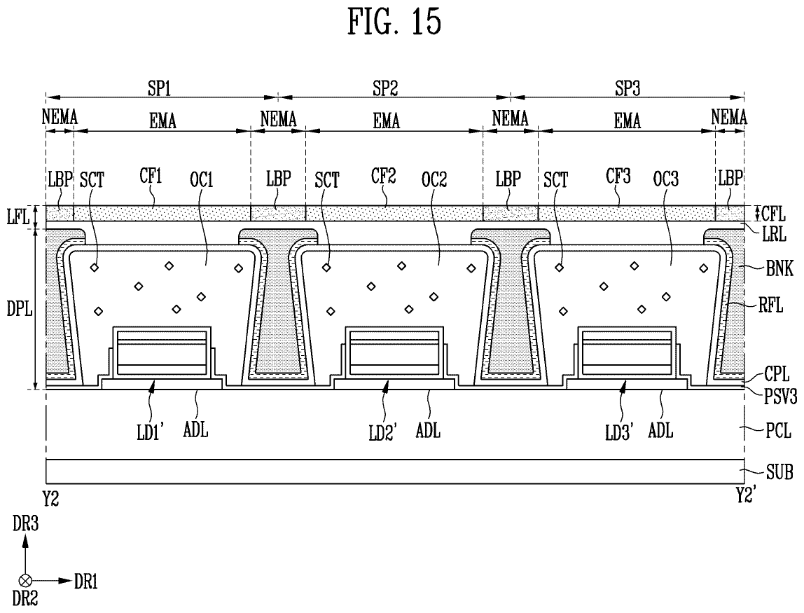

FIG. 14 is a schematic cross-sectional view taken along line X2-X2′ of FIG. 13. FIG. 15 is a schematic cross-sectional view taken along line Y2-Y2′ of FIG. 13.

Referring to FIGS. 13 and 14, the pixel circuit layer PCL, the display element layer DPL, and the light functional layer LFL may be sequentially disposed on the substrate SUB.

The pixel circuit layer PCL is described similarly to that described with reference to FIG. 7. Therefore, a description of an overlapping content may be omitted.

The display element layer DPL may be disposed on the second passivation layer PSV2. The display element layer DPL may include the first anode electrode AE1, the cathode electrode CE, a first reflective electrode RFE1, a second reflective electrode RFE2, the adhesive layer ADL, the first and second bridge electrodes BRE1 and BRE2, the first light emitting element LD1′, the third passivation layer PSV3, the first light extraction structure OC1, the capping layer CPL, the reflective layer RFL, and the first bank layer BNK.

An electrode layer including the first anode electrode AE1 and the cathode electrode CE may be disposed on the pixel circuit layer PCL. The first anode electrode AE1 and the cathode electrode CE are described similarly to those described with reference to FIG. 7. Therefore, a description of an overlapping content may be omitted.

The first reflective electrode RFE1 may cover the first anode electrode AE1. The second reflective electrode RFE2 may cover the cathode electrode CE. The first and second reflective electrodes RFE1 and RFE2 may include a material suitable for reflecting light. For example, the first and second reflective electrodes RFE1 and RFE2 may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto. Accordingly, light emitted from the light emitting element LD1′ may be reflected by the first and second reflective electrodes RFE1 and RFE2, and thus light output efficiency may be improved.

In embodiments, the first and second reflective electrodes RFE1 and RFE2 may be omitted. In this case, the first anode electrode AE1 and the cathode electrode CE may include a material suitable for reflecting light. That is, the first anode electrode AE1 and the cathode electrode CE may perform the function of the first and second reflective electrodes RFE1 and RFE2 described above.

The adhesive layer ADL may be disposed on the first reflective electrode RFE1, the second reflective electrode RFE2, and the second passivation layer PSV2 between the first reflective electrode RFE1 and the second reflective electrode RFE2. The adhesive layer ADL may include an insulating material having an adhesive property. The adhesive layer ADL may serve to fix the first light emitting element LD1′ attached to the adhesive layer ADL.

The first light emitting element LD1′ may include a light emitting stack including a first semiconductor layer 11′, a second semiconductor layer 12′ disposed under the first semiconductor layer 11′, and an active layer 13 disposed between the first semiconductor layer 11′ and the second semiconductor layer 12′. In embodiments, the light emitting stack may further include an auxiliary layer 14′ disposed under the second semiconductor layer 12′.

The first semiconductor layer 11′ may be described similarly to the first semiconductor layer 11 described with reference to FIG. 7. The first semiconductor layer 11′ provides a hole to the active layer 13′. The first semiconductor layer 11′ may include at least one p-type semiconductor material. Hereinafter, a description of an overlapping content may be omitted.

The second semiconductor layer 12′ may be described similarly to the second semiconductor layer 12 described with reference to FIG. 7. The second semiconductor layer 12′ provides an electron to the active layer 13′. The second semiconductor layer 12′ may include at least one n-type semiconductor material. Hereinafter, a description of an overlapping content may be omitted.

The active layer 13′ may be described similarly to the active layer 13 described with reference to 7. The active layer 13′ may be disposed between the first semiconductor layer 11′ and the second semiconductor layer 12′ and may be an area where the electron and the hole are recombined. As the electron and the hole recombine in the active layer 13′, the electron and the hole may transit to a lower energy level, and thus light having a wavelength corresponding thereto may be generated. Hereinafter, a description of an overlapping content may be omitted.

The auxiliary layer 14′ may include a gallium nitride (GaN) semiconductor material in which an impurity is not substantially doped or an impurity is doped with a relatively low concentration, and may configure the n-type semiconductor layer together with the second semiconductor layer 12′.

The first light emitting element LD1′ may include a first bonding electrode BDE1′ and a second bonding electrode BDE2′. The first bonding electrode BDE1′ may be connected to an upper surface of the first semiconductor layer 11′. The first bonding electrode BDE1′ may not physically contact the second semiconductor layer 12′ and the active layer 13′. The second bonding electrode BDE2′ may be connected to the second semiconductor layer 12′ that does not overlap the first semiconductor layer 11′ and the active layer 13′. For example, the second bonding electrode BDE2′ may be connected to the second semiconductor layer 12′ exposed by removing the first semiconductor layer 11′ and the active layer 13′ by etching. The second bonding electrode BDE2′ may not physically contact the first semiconductor layer 11′, the active layer 13′, and the first bonding electrode BDE1′. The first light emitting element LD1′ may be a lateral chip type light emitting element.

The first and second bonding electrodes BDE1′ and BDE2′ may be configured to be substantially transparent or translucent to satisfy a selectable light transmittance. In embodiments, the first and second bonding electrodes BDE1′ and BDE2′ may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, a material of the first and second bonding electrodes BDE1′ and BDE2′ is not limited thereto.

The first light emitting element LD1′ may include an insulating layer 15′ that covers at least a portion of an outer peripheral surface of the light emitting stack. For example, the insulating layer 15′ may entirely cover the outer peripheral surface of the light emitting stack. The insulating layer 15′ may serve to prevent an electrical short circuit that may occur in case that the active layer 13′ contacts a conductive material other than the first semiconductor layer 11′ and the second semiconductor layer 12′. The insulating layer 15′ may serve to prevent an electrical short circuit that may occur in case that the second bonding electrode BDE2′ contacts the first semiconductor layer 11′ and the active layer 13′. The insulating layer 15′ may include a transparent insulating material. As shown in FIG. 14, a portion of the first bonding electrode BDE1′ and a portion of the second bonding electrode BDE2′ may be exposed without being covered by the insulating layer 15′.

The first bonding electrode BDE1′ may extend along the insulating layer 15′ covering a side surface of the light emitting stack. An extended portion of the first bonding electrode BDE1′ and an exposed portion of the first reflective electrode RFE1 on which the adhesive layer ADL is not disposed (an exposed portion of the first anode electrode AE1 in case that the first reflective electrode RFE1 may be omitted) may be electrically connected to each other through the first bridge electrode BRE1. The second bonding electrode BDE2′ may extend along the insulating layer 15′ covering the side surface of the light emitting stack. An extended portion of the second bonding electrode BDE2′ and an exposed portion of the second reflective electrode RFE2 on which the adhesive layer ADL is not disposed (an exposed portion of the cathode electrode CE in case that the second reflective electrode RFE2 may be omitted) may be electrically connected to each other through the second bridge electrode BRE2. The first bridge electrode BRE1 and the second bridge electrode BRE2 may include a same material as one of the first anode electrode AE1, the cathode electrode CE, the first bonding electrode BDE1′, and the second bonding electrode BDE2′, but embodiments are not limited thereto.

The third passivation layer PSV3 entirely covering components such as the first bridge electrode BRE1, the second bridge electrode BRE2, and the first light emitting element LD1′ is disposed on the pixel circuit layer PCL. The third passivation layer PSV3 may protect the components disposed under the third passivation layer PSV3. The third passivation layer PSV3 may include a same material as one of the first passivation layer PSV1, the second passivation layer PSV2, and the interlayer insulating layer ILD, but embodiments are not limited thereto. In embodiments, the third passivation layer PSV3 may not be disposed on an upper surface of the first light emitting element LD1. The third passivation layer PSV3 may be omitted.

The first light extraction structure OC1 is described similarly to that described with reference to FIG. 7. The first light extraction structure OC1 is disposed to overlap the first light emitting element LD1′. In embodiments, the first light extraction structure OC1 may surround at least a portion of a side surface adjacent to an upper surface of the first light emitting element LD1′. Hereinafter, a description of an overlapping content may be omitted.

The capping layer CPL is described similarly to that described with reference to FIG. 7. The capping layer CPL may entirely cover the first light extraction structure OC1 and the third passivation layer PSV3. Hereinafter, a description of an overlapping content may be omitted.

The first bank layer BNK and the reflective layer RFL are described similarly to those described with reference to FIG. 7. The first bank layer BNK1 may be disposed between the first light extraction structure OC1 and the second and third light extraction structures OC2 and OC3 of FIG. 15 to be described later. The reflective layer RFL is disposed between the first bank layer BNK and the first light extraction structure OC1. Hereinafter, a description of an overlapping content may be omitted.

The first light extraction structure OC1 and the reflective layer RFL may serve to improve light output efficiency of light generated in the first light emitting element LD1′. As described above, even though the first light emitting element LD1′ is a lateral chip type, a structure of the first light extraction structure OC1 and the reflective layer RFL for improving light output efficiency of the flip chip type first light emitting element LD1 described with reference to FIG. 7 may be substantially identically (or similarly) applied.

Above, the pixel circuit layer PCL and the display element layer DPL of the first sub-pixel SP1 are described. Each of the second and third sub-pixels SP2 and SP3 of FIG. 13 may be configured similarly to the first sub-pixel SP1, unless otherwise described herein.

The light functional layer LFL is provided on the first bank layer BNK and the capping layer CPL. The light functional layer LFL is described similarly to that described with reference to FIG. 7. The light functional layer LFL may include the filling layer LRL and the color filter layer CFL. Hereinafter, a description of an overlapping content may be omitted.

Referring to FIGS. 13 and 15, the pixel circuit layer PCL, the display element layer DPL, and the light functional layer LFL may be sequentially provided on the substrate SUB.

The pixel circuit layer PCL is described similarly to that described with reference to FIG. 14. In the pixel circuit layer PCL, the sub-pixel circuits corresponding to the first to third sub-pixels SP1, SP2, and SP3 are provided.

The display element layer DPL is described similarly to that described with reference to FIG. 14. In the display element layer DPL, the first to third light emitting elements LD1′, LD2′, and LD3′ respectively corresponding to the first to third sub-pixels SP1, SP2, and SP3 are provided. The first light emitting element LD1′ is connected between the cathode electrode CE of FIG. 14 and the transistor T_SP1 of FIG. 14 included in the sub-pixel circuit of the first sub-pixel SP1. The second light emitting element LD2′ is connected between the cathode electrode CE and the transistor included in the sub-pixel circuit of the second sub-pixel SP2. The third light emitting element LD3′ is connected between the cathode electrode CE and the transistor included in the sub-pixel circuit of the third sub-pixel SP3.

In embodiments, in case that the first sub-pixel SP1 is a red sub-pixel, the first light emitting element LD1′ may be configured to emit red color light. In case that the second sub-pixel SP2 is a green sub-pixel, the second light emitting element LD2′ may be configured to emit green color light. In case that the third sub-pixel SP3 is a blue sub-pixel, the third light emitting element LD3′ may be configured to emit blue color light. As described above, each of the first to third light emitting elements LD1′, LD2′, and LD3′ may be configured to emit light of a color corresponding to a type of a corresponding sub-pixel.

The first to third light extraction structures OC1, OC2, and OC3 respectively corresponding to the first to third light emitting elements LD1′, LD2′, and LD3′ are provided. The first to third light extraction structures OC1, OC2, and OC3 may be disposed to be spaced apart from each other. The first light extraction structure OC1 may cover the first light emitting element LD1′. The second light extraction structure OC2 may cover the second light emitting element LD2′. The third light extraction structure OC3 may cover the third light emitting element LD3′. A side surface of each of the first to third light extraction structures OC1, OC2, and OC3 may include an inversely tapered inclined surface.

The first bank layer BNK and the reflective layer RFL are described similarly to those described with reference to FIG. 8. The first bank layer BNK are provided between the first to third light extraction structures OC1, OC2, and OC3. Accordingly, the first bank layer BNK may surround the first to third light extraction structures OC1, OC2, and OC3. The reflective layer RFL is disposed between the first to third light extraction structures OC1, OC2, and OC3 and the first bank layer BNK. The reflective layer RFL may surround at least a side surface of each of the first to third light extraction structures OC1, OC2, and OC3.

The light functional layer LFL is provided on the display element layer DPL. The light functional layer LFL is described similarly to that described with reference to FIG. 8. Therefore, a description of an overlapping content may be omitted.

Referring to FIGS. 13 to 15 again, instead of the reflective layer RFL shown in FIGS. 14 and 15, the reflective layer RFL′ described with reference to FIGS. 9 and 10 may be applied.

According to embodiments, the first to third light emitting elements LD1′, LD2′, and LD3′ may emit light of the same color. In this case, instead of the light functional layer LFL shown in FIGS. 14 and 15, the light functional layer LFL described with reference to FIGS. 11 and 12 may be applied.

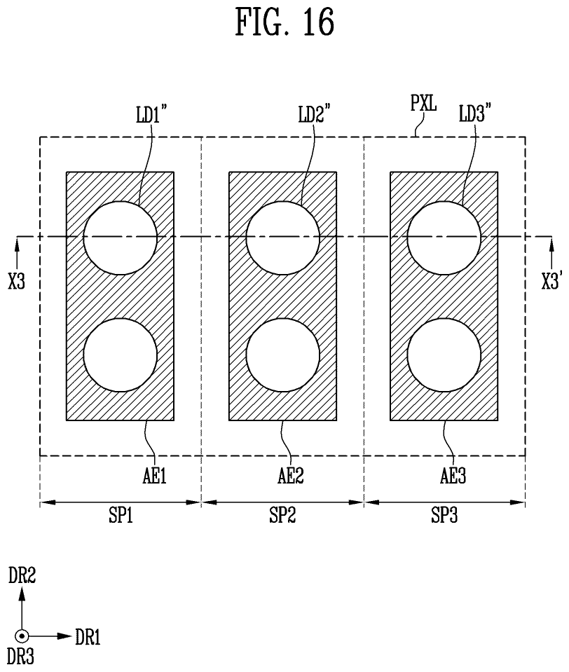

FIG. 16 is a schematic plan view illustrating a third embodiment of one pixel among the pixels included in the display panel of FIG. 3.

Referring to FIG. 16, the pixel PXL may include the first to third sub-pixels SP1, SP2, and SP3. The first to third sub-pixels SP1, SP2, and SP3 may be arranged in the first direction DR1. However, an arrangement of the pixel PXL is not limited thereto and may be variously changed according to embodiments. For example, the first to third sub-pixels SP1, SP2, and SP3 may be arranged in a zigzag pattern.

The first to third anode electrodes AE1, AE2, and AE3 may be disposed in the first to third sub-pixels SP1, SP2, and SP3, respectively. The first anode electrode AE1 may be provided as the anode electrode AE of FIG. 2 included in the sub-pixel circuit SPC of FIG. 2 of the first sub-pixel SP1. The second anode electrode AE2 may be provided as the anode electrode AE included in the sub-pixel circuit SPC of the second sub-pixel SP2. The third anode electrode AE3 may be provided as the anode electrode AE included in the sub-pixel circuit SPC of the third sub-pixel SP3.

On the first to third anode electrodes AE1, AE2, and AE3, one or more first light emitting elements LD1″, one or more second light emitting elements LD2″, and one or more third light emitting elements LD3″ may be disposed. The first light emitting elements LD1″ are connected to the first anode electrode AE1. The second light emitting elements LD2″ are connected to the second anode electrode AE2. The third light emitting elements LD3″ are connected to the third anode electrode AE3. In case that light emitting elements are provided in each sub-pixel, each anode electrode may have a shape extending in a specific direction such as the second direction DR2, and light emitting elements connected thereto may be arranged in the same direction.

The first light emitting elements LD1″ may be provided as the light emitting element LD of FIG. 2 included in the first sub-pixel SP1. The second light emitting elements LD2″ may be provided as the light emitting element LD of FIG. 2 included in the second sub-pixel SP2. The third light emitting elements LD3″ may be provided as the light emitting element LD included in the third sub-pixel SP3. In case that light emitting elements are provided in one sub-pixel, the light emitting elements may be connected in parallel between an anode electrode and a cathode electrode, and may be provided as the light emitting element LD of FIG. 2.

The first light emitting elements LD1″, the second light emitting elements LD2″, and the third light emitting elements LD3″ may be inorganic light emitting diodes including an inorganic light emitting material. However, embodiments are not limited thereto, and for example organic light emitting diodes may be used.

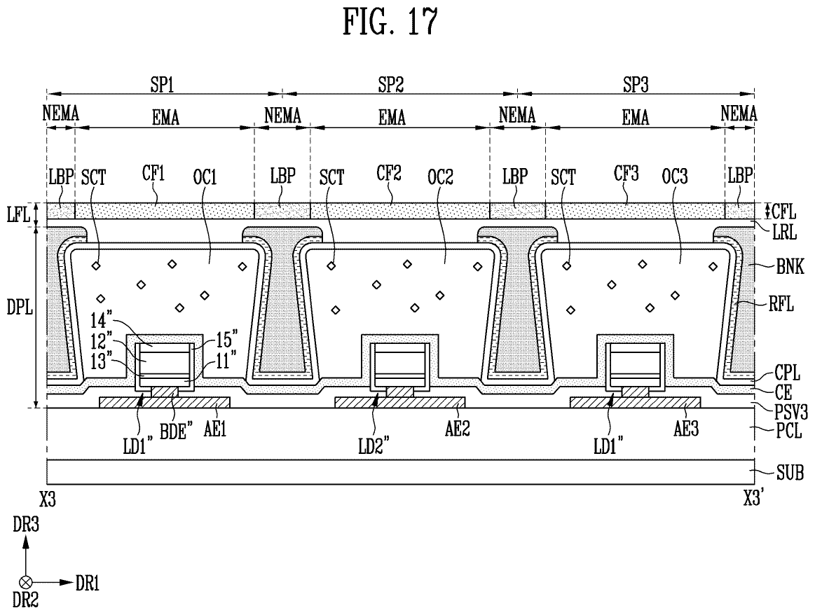

FIG. 17 is a schematic cross-sectional view taken along line X3-X3′ of FIG. 16.

Referring to FIGS. 16 and 17, the pixel circuit layer PCL, the display element layer DPL, and the light functional layer LFL may be sequentially disposed on the substrate SUB.

The pixel circuit layer PCL is described similarly to that described with reference to FIG. 7. Therefore, a description of an overlapping content may be omitted.

On the pixel circuit layer PCL, the first to third anode electrodes AE1, AE2, and AE3 are disposed in the first to third sub-pixels SP1, SP2, and SP3, respectively.

The first anode electrode AE1 may be electrically connected to a transistor included in a first sub-pixel circuit through a contact hole passing through at least a portion of the pixel circuit layer PCL. The second anode electrode AE2 may be electrically connected to a transistor included in a second sub-pixel circuit through a contact hole passing through at least a portion of the pixel circuit layer PCL. The third anode electrode AE3 may be electrically connected to a transistor included in a third sub-pixel circuit through a contact hole passing through at least a portion of the pixel circuit layer PCL.

The first to third light emitting elements LD1″, LD2″, and LD3″ are disposed on the first to third anode electrodes AE1, AE2, and AE3, respectively. The first to third light emitting elements LD1″, LD2″, and LD3″ may be bonded and coupled or connected to the first to third anode electrodes AE1, AE2, and AE3, respectively.

The first light emitting element LD1″ may include a bonding electrode BDE″, a first semiconductor layer 11″, a second semiconductor layer 12″, an active layer 13″, and an auxiliary layer 14″. The first light emitting element LD1″ may be implemented as a vertical light emitting stack in which the bonding electrode BDE″, the first semiconductor layer 11″, the active layer 13″, the second semiconductor layer 12″, and the auxiliary layer 14″ may be sequentially stacked each other along the direction DR3.

The first semiconductor layer 11″ is described similarly to the first semiconductor layer 11 described with reference to FIG. 7. The second semiconductor layer 12″ is described similarly to the second semiconductor layer 12 described with reference to FIG. 7. The active layer 13″ is described similarly to the active layer 13 described with reference to FIG. 7. The auxiliary layer 14″ is described similarly to the auxiliary layer 14 described with reference to FIG. 7. Therefore, a description of an overlapping content may be omitted.

The bonding electrode BDE may be electrically connected to the first semiconductor layer 11″. The bonding electrode BDE may include a eutectic metal.

The first light emitting element LD1″ may further include an insulating layer 15″ covering at least a portion of an outer peripheral surface of the vertical light emitting stack. The insulating layer 15″ may prevent an electrical short circuit that may occur in case that the active layer 13″ contacts a conductive material other than the first and second semiconductor layers 11″ and 12″. The insulating layer 15″ may include a transparent insulating material. As shown in FIG. 17, the insulating layer 15″ is configured to expose at least a portion of the bonding electrode BDE″. The insulating layer 15″ is configured to expose an upper surface of the auxiliary layer 14″ to be in contact with the cathode electrode CE.

A lower surface of the bonding electrode BDE may be connected to the first anode electrode AE1. An upper surface of the auxiliary layer 14″ may be connected to the cathode electrode CE. Accordingly, the first light emitting element LD1″ may be electrically connected between the first anode electrode AE1 and the cathode electrode CE.

According to an embodiments, a reflective electrode may be further disposed between the bonding electrode BDE and the first semiconductor layer 11″. In this case, light emitted from the first light emitting element LD1″ may be output efficiently toward light functional layer LFL. The reflective electrode may be formed of a conductive material having a selectable reflectance. The conductive material may include an opaque metal. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti) and an alloy thereof. However, a material of the reflective electrode is not limited thereto.

Each of the second and third light emitting elements LD2″ and LD3″ is configured similarly to the first light emitting element LD1″. Hereinafter, a description of an overlapping content may be omitted.

The third passivation layer PSV3 is entirely disposed on the pixel circuit layer PCL. The third passivation layer PSV3 may serve to fix the first to third light emitting elements LD1″, LD2″, and LD3″ bonded to the first to third anode electrodes AE1, AE2, and AE3 so that the first to third light emitting elements LD1″, LD2″, and LD3″ do not move. The third passivation layer PSV3 may serve to protect components disposed under the third passivation layer PSV3 from a foreign substance such as dust or moisture. For example, the third passivation layer PSV3 may include at least one of an inorganic insulating layer and an organic insulating layer. For example, the third passivation layer PSV3 may include epoxy, but embodiments are not limited thereto.

In embodiments, the third passivation layer PSV3 may not be disposed on an upper surface of each of the first to third light emitting elements LD1″, LD2″, and LD3″. Each of the first to third light emitting elements LD1″, LD2″, and LD3″ may protrude from the third passivation layer PSV3 in the third direction DR3.

The cathode electrode CE may be disposed on the first to third light emitting elements LD1″, LD2″, and LD3″. The cathode electrode CE may be entirely disposed on the first to third light emitting elements LD1″, LD2″, and LD3″ and the third passivation layer PSV3. The cathode electrode CE may contact the auxiliary layer 14″ of each of the first to third light emitting elements LD1″, LD2″, and LD3″. The cathode electrode CE may be electrically connected to the second power voltage node VSSN of FIG. 2. Accordingly, the second power voltage applied to the second power voltage node VSSN may be transmitted to the first to third light emitting elements LD1″, LD2″, and LD3″ through the cathode electrode CE.

The cathode electrode CE may be configured to be substantially transparent or translucent to satisfy a selectable light transmittance. In embodiments, the cathode electrode CE may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, a material of the cathode electrode CE is not limited thereto.

According to embodiments, an encapsulation layer may be further disposed on the cathode electrode CE. The encapsulation layer may be disposed to entirely cover the cathode electrode CE. The encapsulation layer may protect components under the encapsulation layer, such as the cathode electrode CE and the first to third light emitting elements LD1″, LD2″, and LD3″, from external water, moisture, and the like within the spirit and the scope of the disclosure. The encapsulation layer may include at least one of metal oxides such as silicon nitride, silicon oxide, silicon oxynitride, and aluminum oxide. However, a material of the encapsulation layer is not limited thereto.

The first to third light extraction structures OC1, OC2, and OC3 are disposed on the first to third light emitting elements LD1″, LD2″, and LD3″, respectively. The first light extraction structure OC1 may be disposed to overlap the light emitting element LD1″. The first light extraction structure OC1 may surround at least a portion of a side surface adjacent to an upper surface of the first light emitting element LD1″. The second light extraction structure OC2 may be disposed to overlap the second light emitting element LD2″. The second light extraction structure OC2 may surround at least a portion of a side surface adjacent to an upper surface of the second light emitting element LD2″. The third light extraction structure OC3 may be disposed to overlap the third light emitting element LD3″. The third light extraction structure OC3 may surround at least a portion of a side surface adjacent to an upper surface of the third light emitting element LD3″. The first to third light extraction structures OC1, OC2, and OC3 may be spaced apart from each other.

The capping layer CPL is described similarly to that described with reference to FIGS. 7 and 8. The capping layer CPL may entirely cover the first to third light extraction structures OC1, OC2, and OC3 and the cathode electrode CE.

The first bank layer BNK and the reflective layer RFL are described similarly to those described with reference to FIGS. 7 and 8. The first bank layer BNK is disposed between the first to third light extraction structures OC1, OC2, and OC3. The reflective layer RFL is disposed between the first bank layer BNK and the first to third light extraction structures OC1, OC2, and OC3. The reflective layer RFL may surround at least a side surface of each of the first to third light extraction structures OC1, OC2, and OC3.

The first to third light extraction structures OC1, OC2, and OC3 and the reflective layer RFL may serve to improve light output efficiency of light generated in the first to third light emitting elements LD1″, LD2″, and LD3″. As described above, even though the first to third light emitting elements LD1″, LD2″, and LD3″ are vertical light emitting elements, a structure of the first light extraction structure OC1 and the reflective layer RFL for improving light output efficiency of the flip chip type first light emitting element LD1 described with reference to FIGS. 7 and 8 may be substantially identically (or similarly) applied.

The light functional layer LFL is provided on the first bank layer BNK and the capping layer CPL. The light functional layer LFL is described similarly to that described with reference to FIG. 7. The light functional layer LFL may include the filling layer LRL and the color filter layer CFL.

In embodiments, in case that the first sub-pixel SP1 is a red sub-pixel, the first light emitting element LD1″ may be configured to emit red color light. In case that the second sub-pixel SP2 is a green sub-pixel, the second light emitting element LD2″ may be configured to emit green color light. In case that the third sub-pixel SP3 is a blue sub-pixel, the third light emitting element LD3″ may be configured to emit blue color light. As described above, each of the first to third light emitting elements LD1″, LD2″, and LD3″ may be configured to emit light of a color corresponding to a type of a corresponding sub-pixel. In this case, instead of the reflective layer RFL shown in FIG. 17, the reflective layer RFL′ described with reference to FIGS. 9 and 10 may be applied.

According to embodiments, the first to third light emitting elements LD1″, LD2″, and LD3″ may emit light of the same color. In this case, instead of the light functional layer LFL shown in FIG. 17, the light functional layer LFL described with reference to FIGS. 11 and 12 may be applied.

FIGS. 18 to 24 are diagrams illustrating a method of manufacturing a display device according to an embodiment of the disclosure.

Hereinafter, with reference to FIGS. 18 to 24, a method of manufacturing the display element layer DPL described with reference to FIGS. 6 to 8 is described. In describing FIGS. 18 to 24, a description of a content overlapping the content described with reference to FIGS. 6 to 8 may be omitted.

Referring to FIG. 18, the substrate SUB, the pixel circuit layer PCL, the adhesive layer ADL, the first to third light emitting elements LD1, LD2, and LD3, and the third passivation layer PSV3 may be formed.

Thereafter, an overcoating layer OC may be entirely formed on the third passivation layer PSV3. The overcoating layer OC may have a sufficient thickness in the third direction DR3 to entirely cover the first to third light emitting elements LD1, LD2, and LD3.

Referring to FIG. 19, the overcoating layer OC of FIG. 18 may be exposed and developed to form the first to third light extraction structures OC1, OC2, and OC3.

In an embodiment, the overcoating layer OC may include a negative photoresist material. Here, the negative photoresist material may be a material hardened by exposure, and during development after exposure, an exposed portion of the negative photoresist material may remain and an unexposed portion may be removed. For example, the first to third light extraction structures OC1, OC2, and OC3 may be an exposed portion of the overcoating layer OC.

As described above, as the first to third light extraction structures OC1, OC2, and OC3 are formed by exposure and development of the overcoating layer OC including the negative photoresist material, the side surface of the first to third light extraction structures OC1, OC2, and OC3 may include an inversely tapered inclined surface. In contrast, in case that the first to third light extraction structures OC1, OC2, and OC3 are formed by exposure and development of an overcoating layer OC including a positive photoresist material, the side surface of the first to third light extraction structures OC1, OC2, and OC3 may include a regularly tapered inclined surface.

In embodiments, the overcoating layer OC may include a scattering particle SCT. Therefore, the first to third light extraction structures OC1, OC2, and OC3 formed by exposure and development of the overcoating layer OC may also include the scattering particle SCT.

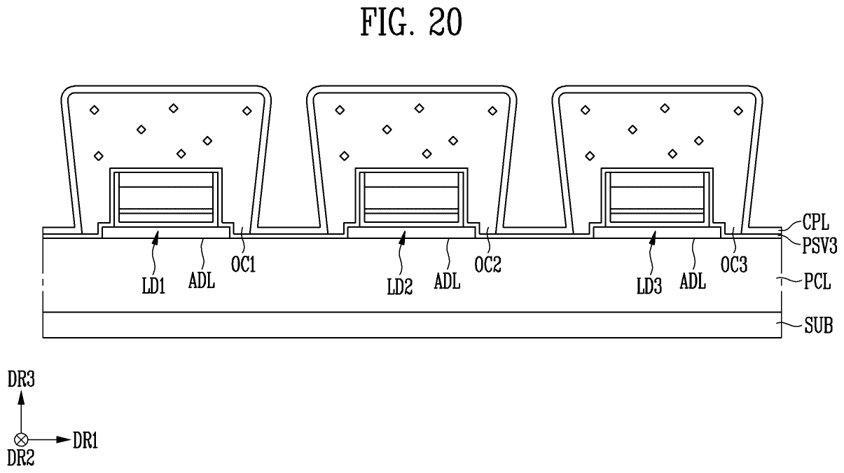

Referring to FIG. 20, the capping layer CPL entirely covering the first to third light extraction structures OC1, OC2, and OC3 and the third passivation layer PSV3 may be formed. There is no limitation in a method of forming the capping layer CPL, and various methods may be used.

Referring to FIG. 21, the reflective layer RFL entirely covering the capping layer CPL may be formed. There is no limitation in a method of forming the reflective layer RFL, and various methods may be used.

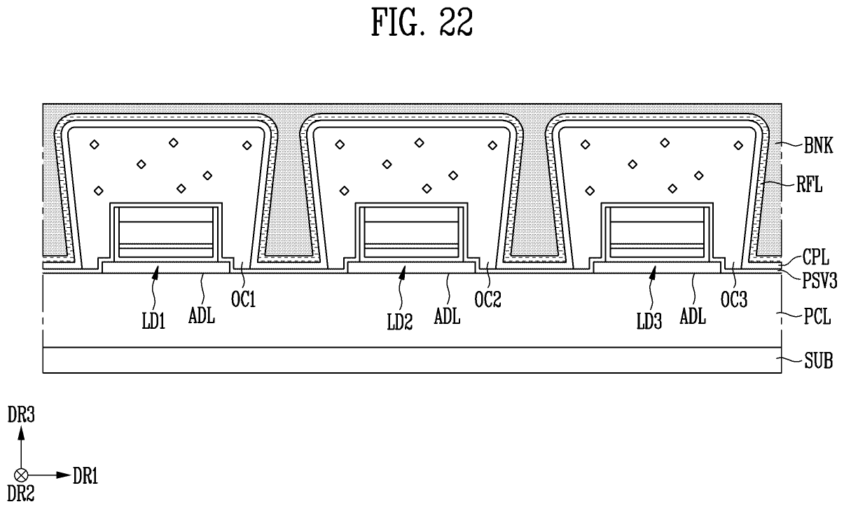

Referring to FIG. 22, the first bank layer BNK entirely covering the reflective layer RFL may be formed. In this case, an upper surface of the first bank layer BNK may be substantially flat. Between the first to third light extraction structures OC1, OC2, and OC3, the lowermost surface of the first bank layer BNK may be entirely covered by the reflective layer RFL.

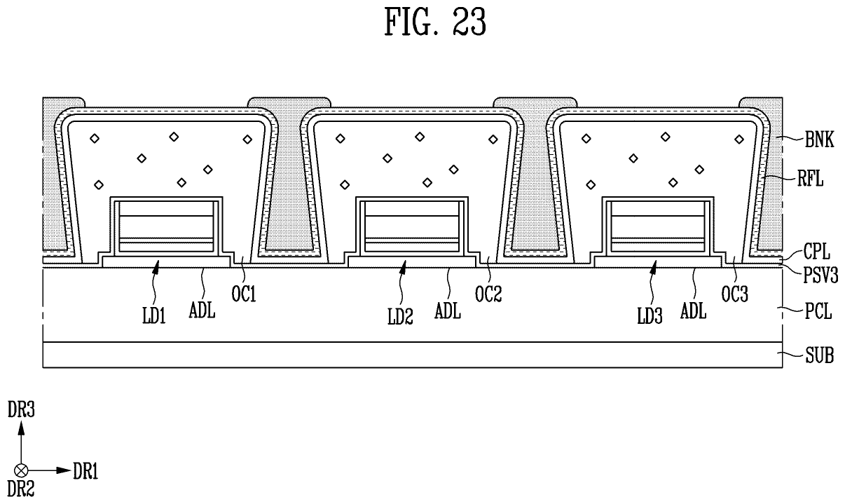

Referring to FIG. 23, the first bank layer BNK disposed in an area overlapping at least a portion of an upper surface of each of the first to third light extraction structures OC1, OC2, and OC3 may be removed by etching. Accordingly, the reflective layer RFL disposed in the area overlapping at least a portion of the upper surface of each of the first to third light extraction structures OC1, OC2, and OC3 may be exposed.

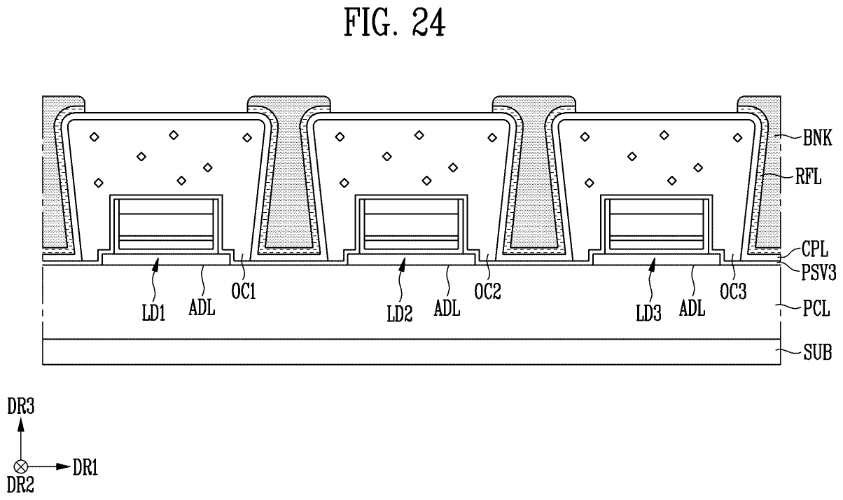

Referring to FIG. 24, the reflective layer RFL may be etched using the first bank layer BNK as a mask. Accordingly, an exposed portion of the reflective layer RFL described with reference to FIG. 23 may be removed. A side surface of the first bank layer BNK and a side surface of the reflective layer RFL may be aligned with each other.

FIGS. 25 to 28 are diagrams illustrating a method of manufacturing a display device according to an embodiment.

Hereinafter, with reference to FIGS. 25 to 28, a method of manufacturing the display element layer DPL described with reference to FIGS. 6, 9, and 10 is described. In describing FIGS. 25 to 28, a description of a content overlapping the content described with reference to FIGS. 6, 9, and 10 may be omitted.

Referring to FIG. 25, the steps described with reference to FIGS. 18 to 21 may be performed. Therefore, a description of an overlapping content may be omitted.

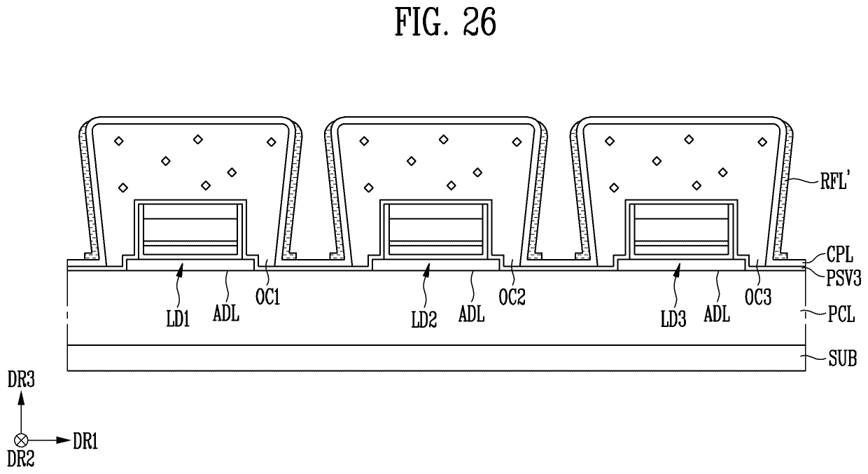

Referring to FIG. 26, the reflective layer RFL disposed in the area overlapping at least a portion of the upper surface of each of the first to third light extraction structures OC1, OC2, and OC3 may be etched.

In an embodiment, etching of the reflective layer RFL may be anisotropic dry etching of the reflective layer RFL. In this case, a portion of the reflective layer RFL surrounding a side surface including an inversely tapered inclined surface of the first to third light extraction structures OC1, OC2, and OC3 may remain without being removed by the anisotropic dry etching. Another portion of the reflective layer RFL disposed on the capping layer CPL between the first to third light extraction structures OC1, OC2, and OC3 adjacent to the above-described portion of the reflective layer RFL may remain without being removed by the anisotropic dry etching. Accordingly, the reflective layer RFL′ described with reference to FIGS. 9 and 10 may be formed. In this case, a portion of the capping layer CPL may be exposed without being covered by the reflective layer RFL′, between the first to third light extraction structures OC1, OC2, and OC3.

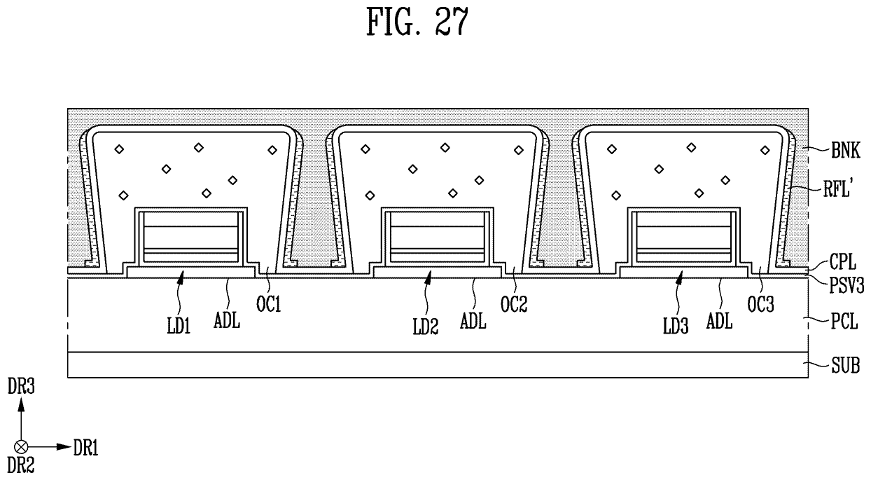

Referring to FIG. 27, the first bank layer BNK entirely covering the capping layer CPL and the reflective layer RFL′ may be formed. In this case, an upper surface of the first bank layer BNK may be substantially flat. The lowermost surface of the first bank layer BNK may not be covered by the reflective layer RFL′ between the first to third light extraction structures OC1, OC2, and OC3 and may contact the exposed capping layer CPL.

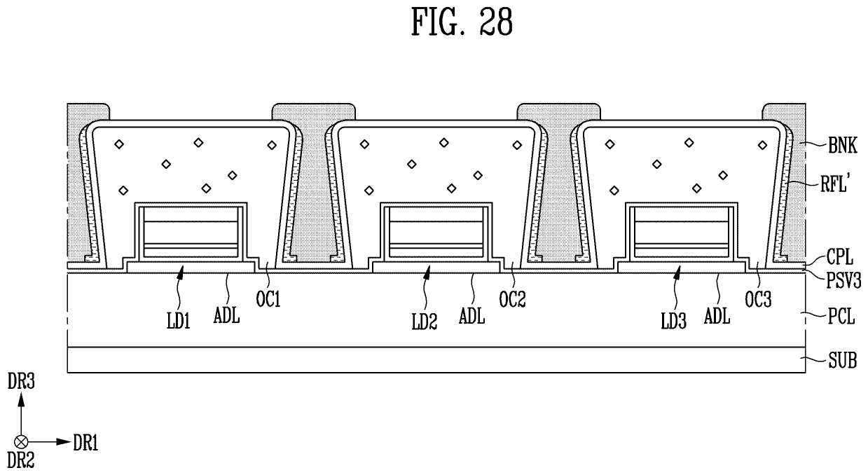

Referring to FIG. 28, the first bank layer BNK disposed in the area overlapping at least a portion of the upper surface of each of the first to third light extraction structures OC1, OC2, and OC3 may be removed by etching. Accordingly, the capping layer CPL disposed in the area overlapping at least a portion of the upper surface of each of the first to third light extraction structures OC1, OC2, and OC3 may be exposed.

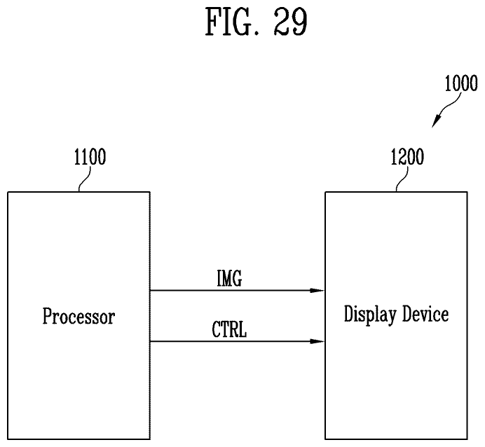

FIG. 29 is a block diagram illustrating a display system according to an embodiment.

Referring to FIG. 29, the display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like within the spirit and the scope of the disclosure. The processor 1100 may be connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

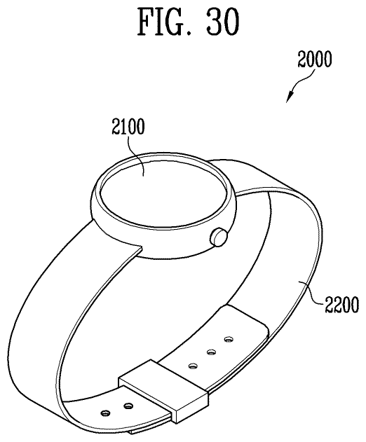

FIGS. 30 to 33 are schematic perspective views illustrating application examples of the display system of FIG. 29.

Referring to FIG. 30, the display system 1000 of FIG. 29 may be applied to a smart watch 2000 including a display unit 2100 and a strap unit 2200.

The smart watch 2000 may be a wearable electronic device. For example, the smart watch 2000 may have a structure in which the strap unit 2200 is mounted on a user's wrist. Here, the display system 1000 and/or the display device 1200 may be applied to the display unit 2100, and image data including time information may be provided to a user.

Referring to FIG. 31, the display system 1000 of FIG. 29 may be applied to an automotive display system 3000. Here, the automotive display system 3000 may include a computing system provided inside and/or outside a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat displays 3600 provided in a vehicle.

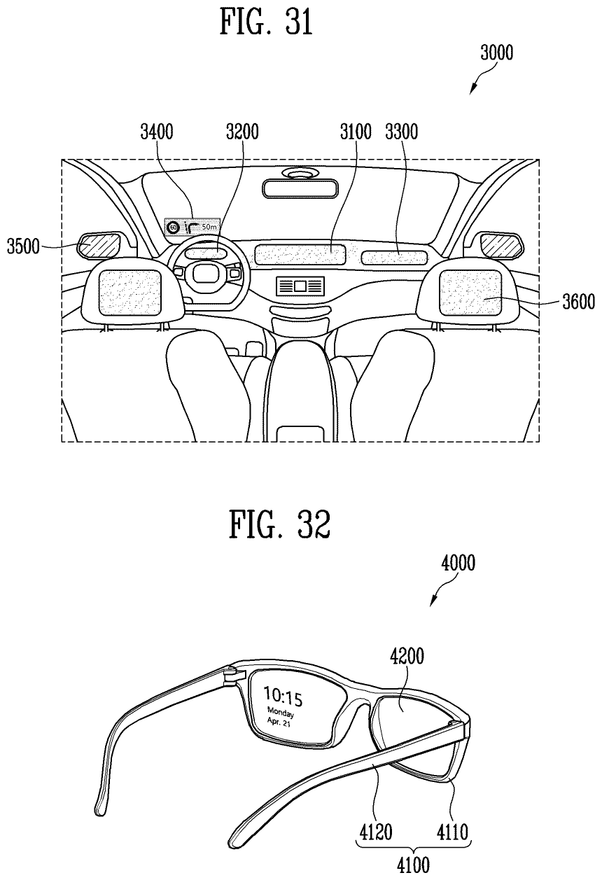

Referring to FIG. 32, the display system 1000 of FIG. 29 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens unit 4200. The frame 4100 may include a housing 4110 that supports the lens unit 4200 and a leg unit 4120 for the user to wear. The leg unit 4120 may be connected to the housing 4110 through a hinge and may be folded or unfolded relative to the housing 4110.

A battery, a touch pad, a microphone, a camera, and the like may be built in the frame 4100. A projector that outputs light, a processor that controls a light signal, and the like may be built in the frame 4100.

The lens unit 4200 may include an optical member that transmits or reflects light. For example, the lens unit 4200 may include glass, transparent synthetic resin, or the like within the spirit and the scope of the disclosure.

In order for user's eyes to recognize visual information, the lens unit 4200 may reflect an image by the light signal transmitted from the projector of the frame 4100 by a rear surface (for example, a surface of a direction facing the user's eyes) of the lens unit 4200. For example, the user may recognize visual information such as time and date displayed on the lens unit 4200. At this time, the projector and/or the lens unit 4200 may be a type of display device. The display device 1200 may be applied to the projector and/or the lens unit 4200.

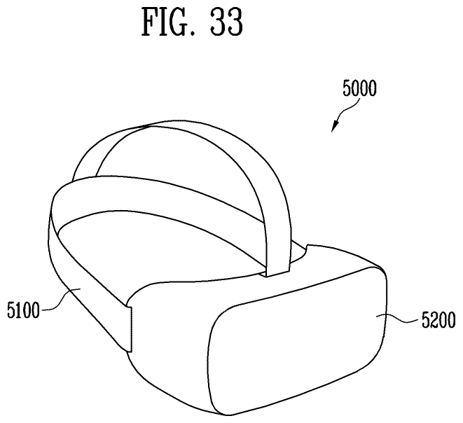

Referring to FIG. 33, the display system 1000 of FIG. 29 may be applied to a head mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mount band 5100 and a display device receiving case 5200. The head mount band 5100 may be connected to the display device receiving case 5200. The head mount band 5100 may include a horizontal band and/or a vertical band for fixing the head mounted display device 5000 to a user's head. The horizontal band may be configured to surround a side portion of the user's head, and the vertical band may be configured to surround an upper portion of the user's head. However, embodiments are not limited thereto. For example, the head mount band 5100 may be implemented in a form of a glasses frame, a helmet, or the like within the spirit and the scope of the disclosure.

The display device receiving case 5200 may receive the display system 1000 and/or the display device 1200.

Although described with reference to the above embodiments, it will be understood that those skilled in the art can variously modify and change the disclosure without departing from the spirit and scope of the disclosure and described in the claims below.

What is claimed is:

1. A display device comprising:
a plurality of light emitting elements disposed on a pixel circuit layer;
a plurality of light extraction structures spaced apart from each other on the pixel circuit layer and overlapping the plurality of light emitting elements;
a first bank layer disposed between the plurality of light extraction structures; and
a reflective layer disposed between the plurality of light extraction structures and the first bank layer, the reflective layer surrounding at least a side surface of each of the plurality of light extraction structures, wherein
each of the plurality of light emitting elements is covered by a corresponding light extraction structure among the plurality of light extraction structures, and
the side surface of each of the plurality of light extraction structures includes a substantially inversely tapered inclined surface.

2. The display device according to claim 1, wherein each of the plurality of light extraction structures includes a negative photoresist material.

3. The display device according to claim 1, wherein the reflective layer is not disposed between a lower surface of each of the plurality of light extraction structures and the pixel circuit layer.

4. The display device according to claim 1, wherein each of the plurality of light extraction structures surrounds at least a portion of a side surface adjacent to an upper surface of a corresponding light emitting element among the plurality of light emitting elements.

5. The display device according to claim 1, wherein each of the plurality of light extraction structures includes a scattering particle.

6. The display device according to claim 1, wherein an upper edge of each of the plurality of light extraction structures has a substantially rounded shape in cross-section.

7. The display device according to claim 1, wherein a side surface between a lower surface and an upper edge of each of the plurality of light extraction structures is a substantially inversely tapered inclined surface in cross-section.

8. The display device according to claim 7, wherein the reflective layer extends from the side surface of each of the plurality of light extraction structures to further cover the upper edge of each of the plurality of light extraction structures and a portion of an upper surface adjacent to the upper edge.

9. The display device according to claim 8, wherein the reflective layer covers a lowermost surface of the first bank layer.

10. The display device according to claim 8, wherein a side surface of the reflective layer and a side surface of the first bank layer are aligned with each other on an upper surface of each of the plurality of light extraction structures.

11. The display device according to claim 7, wherein the reflective layer covers a portion of the upper edge adjacent to the side surface of each of the plurality of light extraction structures and does not cover an upper surface of each of the plurality of light extraction structures.

12. The display device according to claim 11, wherein a lowermost surface of the first bank layer is not covered by the reflective layer.

13. The display device according to claim 1, further comprising:
a plurality of light conversion patterns spaced apart from each other on the plurality of light extraction structures that overlap the plurality of light extraction structures.

14. The display device according to claim 13, further comprising:
a second bank layer overlapping the first bank layer and surrounding each of the plurality of light conversion patterns; and
a light reflective layer disposed between the plurality of light conversion patterns and the second bank layer.

15. A method of manufacturing a display device, the method comprising:
forming a plurality of light emitting elements on a pixel circuit layer;
forming a plurality of light extraction structures spaced apart from each other on the pixel circuit layer that overlap the plurality of light emitting elements;
forming a reflective layer entirely on the pixel circuit layer, the reflective layer covering the plurality of light extraction structures;
forming a first bank layer entirely on the reflective layer, the first bank layer covering the reflective layer;
etching the first bank layer disposed in an area overlapping at least a portion of an upper surface of each of the plurality of light extraction structures; and
etching the reflective layer using the first bank layer as a mask,
wherein each of the plurality of light emitting elements is surrounded by a corresponding light extraction structure among the plurality of light extraction structures, and
a side surface of each of the plurality of light extraction structures includes substantially inversely tapered inclined surface.

16. The method according to claim 15, wherein the forming of the plurality of light extraction structures comprises:
forming an overcoating layer entirely on the pixel circuit layer, the overcoating layer covering the plurality of light emitting elements; and
forming the plurality of light extraction structures by exposing and developing the overcoating layer.

17. The method according to claim 16, wherein the overcoating layer includes a negative photoresist material.

18. A method of manufacturing a display device, the method comprising:
forming a plurality of light emitting elements on a pixel circuit layer;
forming a plurality of light extraction structures spaced apart from each other on the pixel circuit layer and overlapping the plurality of light emitting elements;
forming a reflective layer entirely on the pixel circuit layer, the reflective layer covering the plurality of light extraction structures;
etching the reflective layer disposed in an area overlapping at least a portion of an upper surface of each of the plurality of light extraction structures;
forming a first bank layer entirely on the pixel circuit layer, the first bank layer covering the plurality of light extraction structures and the reflective layer; and
etching the first bank layer disposed in an area overlapping at least a portion of the upper surface of each of the plurality of light extraction structures,
wherein each of the plurality of light emitting elements is surrounded by a corresponding light extraction structure among the plurality of light extraction structures, and
a side surface of each of the plurality of light extraction structures includes a substantially inversely tapered inclined surface.

19. The method according to claim 18, wherein the etching of the reflective layer includes anisotropic dry etching the reflective layer.

20. The method according to claim 19, wherein a portion of the reflective layer disposed between the plurality of light extraction structures is etched in etching the reflective layer.
